(19) United States
(12) Patent Application Publication
(10) Pub. No.: US 2009/0002044 A1
(43) Pub. Date: Jan. 1, 2009

(54) Master-slave type flip-flop circuit

(75) Inventor: Shinichiro Kobayashi, Hino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, TOKYO (JP)

(21) Appl. No.: 12/213,519

(22) Filed: Jun. 20, 2008

(30) Foreign Application Priority Data
Jun. 29, 2007 (JP) 2007-172874
Jul. 10, 2007 (JP) 2007-180588

(51) Int. Cl. H03K 3/289

(52) U.S. Cl. 327/203; 327/202

(57) ABSTRACT

A master-slave type flip-flop circuit consisting of a master latch and a slave latch, wherein the master latch comprises: a first clocked inverter to which data are input and a first latch circuit configuring a closed circuit with a first inverter and a second clocked inverter so that an output of the first clocked inverter is input to the first inverter and; the slave latch comprises: a transmission gate to which an output from the first latch circuit is input and a second latch circuit configuring a closed circuit with a second inverter and a third clocked inverter so that an output of the transmission gate is input to the second inverter, respective components configuring the master latch and the slave latch are configured with Sea Of Gate (hereinafter to be referred to as SOG) configuring a gate array, a basic cell of the SOG consists of triplely arrayed N-type transistors and corresponding triplely arrayed P-type transistors, the triplely arrayed N-type transistors consist of double-arrayed normally sized main transistors and one auxiliary transistor sized smaller than in a normal size and the triplely arrayed P-type transistors consist of double-arrayed normally sized main transistors and one auxiliary transistor sized smaller than in a normal size.

The entire disclosure of Japanese Patent Applications No. 2007-172874 filed Jun. 29, 2007 and No. 2007-180588 filed Jul. 10, 2007, is expressly incorporated by reference herein.

### BACKGROUND OF THE INVENTION

1. Field of the Invention

The invention relates to a master-slave type flip-flop circuit consisting of a master latch and a slave latch.

In addition, the invention relates to a master-slave type flip-flop circuit comprising a master latch and a slave latch and being applicable to scan design being one of test simplification designs of an integrated circuit.

2. Description of the Related Art

A conventional master-slave type flip-flop circuit comprises a master latch 300 and a slave latch 400 as illustrated, for example, in FIG. 33.

The master latch 300 comprises an inverter 301, transmission gate 302 and a latch circuit 303. The latch circuit 303 comprises inverters 304 and 305 and transmission gate 306. The slave latch 400 comprises transmission gate 401, a latch circuit 402 and an inverter 403. The latch circuit 402 consists of inverters 404 and 405 and transmission gate 406.

With such configured master-slave type flip-flop, a clock operates transmission gates 302, 306, 401 and 406 so that data stored in the master latch 300 are taken in and data stored in the slave latch 400 are output.

On the other hand, a conventional master-slave type flip-flop circuit, which is applied to scan design being one of test simplification designs of an integrated circuit, is known to comprise a master latch 500 and a slave latch 600 as illustrated, for example, in FIG. 34.

The master latch 500 comprises inverters 501, 503 and 505, transmission gates 502, 504 and 506 and a latch circuit 507. The latch circuit 507 consists of inverters 508 and 509 and transmission gate 510. The slave latch 600 comprises transmission gate 601, a latch circuit 602 and an inverter 603. The latch circuit 602 consists of inverters 604 and 605 and transmission gate 606.

With such configured flip-flop circuit, a clock operates transmission gates 506, 510, 601 and 606. In addition, transmission gates 502 and 504 are operated by a scan enable signal.

Therefore, at the time of a test operation, scan data being input to the inverter 503 are taken and stored by the latch circuit 507. Moreover, those data are stored by the latch circuit 602 and thereafter output through the inverter 603. On the other hand, at the time of a normal operation, data being input to the inverter 501 are taken and stored by the latch circuit 507. Moreover, those data are stored by the latch circuit 602 and thereafter output through the inverter 603.

A master-slave type flip-flop circuit as illustrated in FIG. 33 or FIG. 34 is suitable for configuring an integrated circuit with an MOS integrated circuit with an MOS transistor. In that case, a CMOS inverter is the basis of an inverter.

The CMOS inverter is configured by combining a P-type and an N-type MOS transistors. A P-type MOS transistor is put on and then charges a load. In addition, an N-type MOS transistor is put on and then discharges the electric charges of the load. Consequently, charge and discharge current flow. On the other hand, when the P-type and the N-type MOS transistors are put on concurrently, a pass-through current flows through both MOS transistors.

With thus operated CMOS inverter, charge and discharge currents influence the operation speed. Nevertheless, the pass-through current does not influence the operation speed at all but only be consumed as a current. Therefore, in the case where a pass-through current is significant and the current change amount thereof is significant, noise amount due to EMI (electromagnetic interference) will become significant, giving rise to failure. In addition, in the case where a pass-through current is significant and a current change amount (dI/dt) per unit time is significant, the EMI noise amount increases, giving rise to failure.

In order to eliminate such failure, a clocked inverter with a P-type and an N-type MOS transistors being added to a CMOS inverter is known. In addition, a flip-flop circuit including a clocked inverter is known (for example, refer to JP-A-62-71322 or JP-A-05-75401).

According to a flip-flop circuit including a clocked inverter, influence of charge and discharge currents in a CMOS inverter is avoided. By protecting an occurrence of a pass-through current, reduction in power consumption and EMI can be planned.

Here, in the case where a flip-flop circuit including a clocked inverter is realized by a gate array, besides the clocked inverter, various kinds of logic circuits are included so that the inverter, the transmission gate and the like thereof will be formed with basic cells.

In such a case, a basic cell of the gate array will form various kinds of logic circuits such as a clocked inverter, an inverter and a transmission gate will be formed. Accordingly, the basic cell is desired to be effectively utilized to form respective logic circuits in the case of forming those respective kinds of logic circuits and to secure a wiring resource (wiring region).

Moreover, the flip-flop circuit configured by the gate array made of such basic cells is desired to realize reduction in power consumption and EMI.

Accordingly, in view of the points described above, an advantage of the some aspects of the invention is to provide a master-slave type flip-flop circuit made to plan reduction in power consumption and EMI in the case of being realized with a gate array.

Another object of the invention is to provide a master-slave type flip-flop circuit which is made to utilize a basic cell effectively in the case of being realized with a gate array.

### SUMMARY OF THE INVENTION

A master-slave type flip-flop circuit of the invention is a master-slave type flip-flop circuit consisting of a master latch and a slave latch, wherein the master latch comprises: a first clocked inverter to which data are input and a first latch circuit configuring a closed circuit with a first inverter and a second clocked inverter so that an output of the first clocked inverter is input to the first inverter and; the slave latch comprises: a transmission gate to which an output from the first latch circuit is input and a second latch circuit configuring a closed circuit with a second inverter and a third clocked inverter so that an output of the transmission gate is input to the second inverter, respective components configuring the master latch and the slave latch are configured with Sea Of Gate (hereinafter to be referred to as SOG) configuring a gate array, a basic cell of the SOG consists of triplely arrayed N-type transistors and corresponding triplely arrayed P-type transistors, the triplely arrayed N-type transistors consist of double-arrayed normally sized main transistors and one auxiliary transistor sized smaller than in a normal size and the triplely arrayed P-type transistors consist of double-arrayed normally sized main transistors and one auxiliary transistor sized smaller than in a normal size.

Implementation of the invention further comprises a clock supply circuit supplying the master latch and the slave latch respectively with a clock, wherein the clock supply circuit consists of a third inverter inverting a logic of a clock signal being input and a fourth inverter inverting an output logic of the third inverter; and the third and fourth inverters are configured with the basic cell.

For implementation of the invention, the first clocked inverter consists of a fifth inverter and two first switches carrying out on-off control of a logic of an output of the fifth inverter; the fifth inverter is configured by P-type and N-type main transistors configuring the basic cell and the two first switches are configured by P-type and N-type auxiliary transistors configuring the same basic cell; the second and third clocked inverters respectively consist of a sixth inverter and two second switches carrying out on-off control between the sixth inverter and a power supply as well as the ground; the sixth inverter is configured by P-type and N-type main transistors configuring the basic cell and the two second switches are configured by P-type and N-type auxiliary transistors configuring the same basic cell and the first inverter, the transmission gate and the second inverter are respectively configured by P-type and N-type main transistors configuring the basic cell.

For implementation of the invention, the third inverter is configured by P-type and N-type auxiliary transistors configuring the basic cell and the fourth inverter is configured by bringing two P-type main transistors and two N-type main transistors configuring the same basic cell into cascade connection.

A master-slave type flip-flop circuit of the invention is a master-slave type flip-flop circuit consisting of a master latch and a slave latch, wherein the master latch comprises: a first clocked inverter to which data are input and a first latch circuit configuring a closed circuit with a first inverter and a first clocked NAND gate so that an output of the first clocked inverter is input to the first inverter and the reset signal is input to the first clocked NAND gate and wherein the slave latch comprises: a transmission gate to which an output from the first latch circuit is input and a second latch circuit configuring a closed circuit with a first NAND gate and a second clocked inverter so that an output of the transmission gate and the reset signal are input to the second clocked NAND gate and respective components configuring the master latch and the slave latch are configured with SOG configuring a gate array, a basic cell of the SOG consists of triplely arrayed N-type transistors and corresponding triplely arrayed P-type transistors, the triplely arrayed N-type transistors consist of double-arrayed normally sized main transistors and one auxiliary transistor sized smaller than in a normal size and the triplely arrayed P-type transistors consist of double-arrayed normally sized main transistors and one auxiliary transistor sized smaller than in a normal size.

For implementation of the invention, the first clocked inverter consists of a third inverter and two first switches carrying out on-off control of a logic of an output of the third inverter; the third inverter is configured by P-type and N-type main transistors configuring the basic cell and the two first switches are configured by P-type and N-type auxiliary transistors configuring the same basic cell; the second clocked inverter consists of a fourth inverter and two second switches carrying out on-off control between the fourth inverter and a power supply as well as the ground; the fourth inverter is configured by P-type and N-type main transistors configuring the basic cell and the two second switches are configured by P-type and N-type auxiliary transistors configuring the same basic cell and the first clocked NAND gate consists of NAND gate and a third switch carrying out on-off control of connection between the NAND gate and a power supply as well as the ground; the NAND gate is configured by four P-type and N-type main transistors configuring the basic cell and the two third switches are configured by the two remaining P-type and N-type auxiliary transistors of the same basic cell; and the first inverter and the transmission gate are respectively configured by P-type and N-type main transistors configuring the basic cell and the first NAND gate is configured by P-type and N-type main transistors and a auxiliary transistor configuring the basic cell.

A master-slave type flip-flop circuit of the invention is a master-slave type flip-flop circuit consisting of a master latch and a slave latch, wherein the master latch comprises: a first clocked inverter to which data are input and a first latch circuit configuring a closed circuit with a first NAND gate and a second clocked inverter so that a logic of an output of the first clocked inverter and the set signal are input to the first NAND gate and; the slave latch comprises: a transmission gate to which an output from the first latch circuit is input and a second latch circuit configuring a closed circuit with a first inverter and a first clocked NAND gate so that an output of the transmission gate is input to the first inverter and the reset signal is input to the first clocked NAND gate, respective components configuring the master latch and the slave latch are configured with SOG configuring a gate array, a basic cell of the SOG consists of triplely arrayed N-type transistors and corresponding triplely arrayed P-type transistors, the triplely arrayed N-type transistors consist of double-arrayed normally sized main transistors and one auxiliary transistor sized smaller than in a normal size and the triplely arrayed P-type transistors consist of double-arrayed normally sized main transistors and one auxiliary transistor sized smaller than in a normal size.

For implementation of the invention, the first clocked inverter consists of a third inverter and two first switches carrying out on-off control of a logic of an output of the third inverter; the third inverter is configured by P-type and N-type main transistors configuring the basic cell and the two first switches are configured by P-type and N-type auxiliary transistors configuring the same basic cell; the second clocked inverter consists of a fourth inverter and two second switches carrying out on-off control of connection between the fourth inverter and a power supply as well as the ground; the fourth inverter is configured by P-type and N-type main transistors configuring the basic cell and the two second switches are configured by P-type and N-type auxiliary transistors configuring the same basic cell and the first clocked NAND gate consists of NAND gate and a third switch carrying out on-off control of connection between the NAND gate and a power supply as well as the ground; the NAND gate is configured by four P-type and N-type main transistors configuring the basic cell and the two third switches are configured by the two remaining P-type and N-type auxiliary transistors of the same basic cell; and the first NAND gate, the transmission gate and the first inverter are respectively configured by P-type and N-type main transistors configuring the basic cell.

A master-slave type flip-flop circuit of the invention is a master-slave type flip-flop circuit consisting of a master latch and a slave latch, wherein the master latch comprises: a first clocked inverter to which data are input and a first latch circuit configuring a closed circuit with a first NAND gate and a first clocked NAND gate so that a logic of an output of the first clocked inverter and the reset signal are respectively input to the first NAND gate and the set signal is input to the first clocked NAND gate, wherein the slave latch comprises: a transmission gate to which an output from the first latch circuit is input and a second latch circuit configuring a closed circuit with a second NAND gate and a second clocked NAND gate so that the reset signal is input to the second NAND gate and the set signal is input to the second clocked NAND gate and respective components configuring the master latch and the slave latch are configured with SOG configuring a gate array, a basic cell of the SOG consists of triplely arrayed N-type transistors and corresponding triplely arrayed P-type transistors, the triplely arrayed N-type transistors consist of double-arrayed normally sized main transistors and one auxiliary transistor sized smaller than in a normal size and the triplely arrayed P-type transistors consist of double-arrayed normally sized main transistors and one auxiliary transistor sized smaller than in a normal size.

For implementation of the invention, the first clocked inverter consists of a third inverter and two first switches carrying out on-off control of a logic of an output of the third inverter; the third inverter is configured by two P-type and N-type main transistors configuring the basic cell and the two first switches are configured by P-type and N-type auxiliary transistors configuring the same basic cell; the first clocked NAND gate and the second clocked NAND gate respectively consist of NAND gate and a second switches carrying out on-off control of connection between that NAND gate and a power supply as well as the ground; the NAND gate is configured by four P-type and N-type main transistors configuring a basic cell and the second switch is configured by the two remaining P-type and N-type auxiliary transistors of the same basic cell; and the first NAND gate, the transmission gate and the second NAND gate are respectively configured by P-type and N-type main transistors configuring the basic cell.

A master-slave type flip-flop circuit of the invention is a master-slave type flip-flop circuit consisting of a master latch and a slave latch, wherein the master latch comprises: a first enabled clocked inverter to which data are input at the time of a normal operation; a second enabled clocked inverter to which scan data are input at the time of a test operation; a first inverter selectively controlling an operation of the first enabled clocked inverter and an operation of the second enabled clocked inverter based on a scan enable signal; a first latch circuit configuring a closed circuit with a second inverter and a first clocked NAND gate so that a logic of an output of the first or second enabled clocked inverter is input to the second inverter and a reset signal is input to the first clocked NAND gate; the slave latch comprises: a transmission gate to which an output from the first latch circuit is input and a second latch circuit configuring a closed circuit with a first NAND gate and a first clocked inverter so that an output of the transmission gate and the reset signal are input to the first NAND gate, respective components configuring the master latch and the slave latch are configured with SOG configuring a gate array, a basic cell of the SOG consists of triplely arrayed N-type transistors and corresponding triplely arrayed P-type transistors, the triplely arrayed N-type transistors consist of double-arrayed normally sized main transistors and one auxiliary transistor sized smaller than in a normal size and the triplely arrayed P-type transistors consist of double-arrayed normally sized main transistors and one auxiliary transistor sized smaller than in a normal size.

Implementation of the invention further comprises a clock supply circuit supplying the master latch and the slave latch respectively with a clock, wherein the clock supply circuit consists of a third inverter inverting a logic of a clock signal being input and a fourth inverter inverting an output logic of the third inverter; and the third and fourth inverters are configured with the basic cell.

For implementation of the invention, the first and second enabled clocked inverters respectively consist of first CMOS inverters; two first switches carrying out on-off control of a logic of an output of the first CMOS inverter and two second switches carrying out on-off control of connection between the first CMOS inverter and a power supply as well as the ground based on a scan enable signal; the first CMOS inverter is configured by P-type and N-type main transistors configuring the basic cell; the two first switches are configured by P-type and N-type auxiliary transistors configuring the same basic cell; the two second switches are configured by P-type and N-type main transistors configuring the same basic cell; the first clocked NAND gate consists of a NAND gate and a third switch carrying out on-off control of connection between the NAND gate and a power supply as well as the ground; the NAND gate is configured with four P-type and N-type main transistors configuring the basic cell and the two third switches are configured by the two remaining P-type and N-type auxiliary transistors of the same basic cell; and the first clocked inverter consists of a second CMOS inverter and two second switches carrying out on-off control of connection between the second CMOS inverter and a power supply as well as the ground; the second CMOS inverter is configured by P-type and N-type main transistors configuring the basic cell and the two second switches are configured by P-type and N-type auxiliary transistors configuring the same basic cell; the first inverter is configured by P-type and N-type auxiliary transistors configuring the same basic cell; and the second inverter and the transmission gate are respectively configured by P-type and N-type main and auxiliary transistors configuring the basic cell; and the first NAND gate is configured by P-type and N-type main transistors configuring the basic cell.

For implementation of the invention, the third inverter consists of a CMOS inverter and the CMOS inverter is configured by P-type and N-type auxiliary transistors configuring the basic cell; the fourth inverter consists of a CMOS inverter and the CMOS inverter is configured by bringing two P-type main transistors and two N-type main transistors configuring the same basic cell into cascade connection.

A master-slave type flip-flop circuit of the invention is a master-slave type flip-flop circuit consisting of a master latch and a slave latch, wherein the master latch comprises: a first enabled clocked inverter to which data are input at the time of a normal operation; a second enabled clocked inverter to which scan data are input at the time of a test operation; a first inverter selectively controlling an operation of the first enabled clocked inverter and an operation of the second enabled clocked inverter based on a scan enable signal; a first latch circuit configuring a closed circuit with a first NAND gate and a first clocked inverter so that a logic of an output of the first or second enabled clocked inverter and a set signal are respectively input to the first NAND gate; the slave latch comprises: a transmission gate to which an output from the first latch circuit is input and a second latch circuit configuring a closed circuit with a second inverter and a first clocked NAND gate so that an output of the transmission gate is input to the second inverter and a reset signal is input to the first clocked NAND gate; respective components configuring the master latch and the slave latch are configured with SOG configuring a gate array, a basic cell of the SOG consists of triplely arrayed N-type transistors and corresponding triplely arrayed P-type transistors, the triplely arrayed N-type transistors consist of double-arrayed normally sized main transistors and one auxiliary transistor sized smaller than in a normal size and the triplely arrayed P-type transistors consist of double-arrayed normally sized main transistors and one auxiliary transistor sized smaller than in a normal size.

For implementation of the invention, the first and second enabled clocked inverters respectively consist of first CMOS inverters; two first switches carrying out on-off control of a logic of an output of the first CMOS inverter and two second switches carrying out on-off control of connection between the first CMOS inverter and a power supply as well as the ground based on a scan enable signal; the first CMOS inverter is configured by P-type and N-type main transistors configuring the basic cell; the two first switches are configured by P-type and N-type auxiliary transistors configuring the same basic cell; the two second switches are configured by P-type and N-type main transistors configuring the same basic cell; the first clocked inverter consists of a first CMOS inverter and two third switches carrying out on-off control of an output of the first CMOS inverter; the first CMOS inverter is configured by P-type and N-type main transistors configuring the basic cell and the two third switches are configured by P-type and N-type auxiliary transistors configuring the same basic cell; the first clocked NAND gate consists of a NAND gate and a fourth switch carrying out on-off control of connection between the NAND gate and a power supply as well as the ground; the NAND gate is configured by four P-type and N-type main transistors configuring the basic cell and the two fourth switches are configured by the two remaining P-type and N-type auxiliary transistors of the same basic cell; and the first inverter is configured by P-type and N-type auxiliary transistors configuring the basic cell; and the first NAND gate, the transmission gate and the second inverter are respectively configured by P-type and N-type main transistors configuring the basic cell.

A master-slave type flip-flop circuit of the invention is a master-slave type flip-flop circuit consisting of a master latch and a slave latch, wherein the master latch comprises: a first enabled clocked inverter to which data are input at the time of a normal operation; a second enabled clocked inverter to which scan data are input at the time of a test operation; a first inverter selectively controlling an operation of the first enabled clocked inverter and an operation of the second enabled clocked inverter based on a scan enable signal; a first latch circuit configuring a closed circuit with a first NAND gate and a first clocked NAND gate so that a logic of an output of the first or second enabled clocked inverter and the set signal are respectively input to the first NAND gate and the reset signal is input to the first clocked NAND gate and wherein the slave latch comprises: a transmission gate to which an output from the first latch circuit is input and a second latch circuit configuring a closed circuit with a second NAND gate and a second clocked NAND gate so that the reset signal is input to the second NAND gate and the set signal is input to the second clocked NAND gate and respective components configuring the master latch and the slave latch are configured with SOG configuring a gate array, a basic cell of the SOG consists of triplely arrayed N-type transistors and corresponding triplely arrayed P-type transistors, the triplely arrayed N-type transistors consist of double-arrayed normally sized main transistors and one auxiliary transistor sized smaller than in a normal size and the triplely arrayed P-type transistors consist of double-arrayed normally sized main transistors and one auxiliary transistor sized smaller than in a normal size.

For implementation of the invention, the first and second enabled clocked inverters respectively consist of first CMOS inverters; two first switches carrying out on-off control of a logic of an output of the first CMOS inverter and two second switches carrying out on-off control of connection between the first CMOS inverter and a power supply as well as the ground based on a scan enable signal; the first CMOS inverter is configured by P-type and N-type main transistors configuring the basic cell; the two first switches are configured by P-type and N-type auxiliary transistors configuring the same basic cell; the two second switches are configured by P-type and N-type main transistors configuring the same basic cell; the first clocked NAND gate and the second clocked NAND gate respectively consist of NAND gate and a third switch carrying out on-off control of connection between the NAND gate and a power supply as well as the ground; the NAND gate is configured by four P-type and N-type main transistors configuring the basic cell and the third switches are configured by the two remaining P-type and N-type auxiliary transistors of the same basic cell; and the first inverter is configured by P-type and N-type auxiliary transistors configuring the basic cell; and the first NAND gate, the transmission gate and the second NAND gate are respectively configured by P-type and N-type main transistors configuring the basic cell.

According to thus configured present invention, reduction in power consumption and EMI can be planned in the case of being realized with a gate array.

In addition, according to the invention, a basic cell can be utilized effectively at the occasion of forming various kinds of logic circuits and, moreover, can be planned to secure wiring resource to simplify wiring in the case of being realized with a gate array.

### BRIEF DESCRIPTION OF THE DRAWINGS

FIG. 1 is a circuit diagram illustrating a configuration of a first embodiment of the invention;

FIG. 2 is a plan diagram illustrating a basic cell of a gate array to which the first embodiment is applied;

FIGS. 3A and 3B are the circuit diagrams illustrating a specific configuration of the clocked inverter in FIG. 1;

FIG. 4 is a circuit diagram illustrating a specific configuration of the inverter in FIG. 1;

FIG. 5 is a circuit diagram illustrating a specific configuration of another clocked inverter in FIG. 1;

FIG. 6 is a circuit diagram illustrating a specific configuration of the transmission gate in FIG. 1;

FIG. 7 is a circuit diagram illustrating a specific configuration of another inverter in FIG. 1;

FIG. 8 is a circuit diagram illustrating a specific configuration of still another inverter in FIG. 1;

FIG. 9 is a plan diagram illustrating a part of a gate array in the case of configuring the first embodiment with a gate array;

FIG. 10 is a plan diagram exemplifying a circuit on the first layer of the gate array thereof;

FIG. 11 is a plan diagram exemplifying a circuit on the second layer of the gate array thereof;

FIGS. 12A and 12B are the diagrams illustrating a result of measuring a frequency component of noise included in a power supply current;

FIG. 13 is a circuit diagram illustrating a configuration of a second embodiment of the invention;

FIG. 14 is a circuit diagram illustrating a specific configuration of a clocked NAND gate in FIG. 13;

FIG. 15 is a circuit diagram illustrating a specific configuration of a NAND gate in FIG. 13;

FIG. 16 is a circuit diagram illustrating a configuration of a third embodiment of the invention;

FIG. 17 is a circuit diagram illustrating a specific configuration of a NAND gate in FIG. 16;

FIG. 18 is a circuit diagram illustrating a configuration of a fourth embodiment of the invention;

FIG. 19 is a circuit diagram illustrating a configuration of a fifth embodiment of the invention;

FIG. 20 is a circuit diagram illustrating a configuration of a sixth embodiment of the invention;

FIGS. 21A and 21B are the circuit diagrams illustrating a specific configuration of the enabled clocked inverter in FIG. 20;

FIG. 22 is a circuit diagram illustrating a specific configuration of the inverter in FIG. 20;

FIG. 23 is a circuit diagram illustrating a specific configuration of another inverter in FIG. 20;

FIG. 24 is a circuit diagram illustrating a specific configuration of the clocked NAND gate in FIG. 20;

FIG. 25 is a circuit diagram illustrating a specific configuration of the transmission gate in FIG. 20;

FIG. 26 is a circuit diagram illustrating a specific configuration of the NAND gate in FIG. 20;

FIG. 27 is a circuit diagram illustrating a specific configuration of the clocked inverter in FIG. 20;

FIG. 28 is a circuit diagram illustrating a specific configuration of another inverter in FIG. 20;

FIG. 29 is a circuit diagram illustrating a configuration of a seventh embodiment of the invention;

FIG. 30 is a circuit diagram illustrating a specific configuration of the NAND gate in FIG. 29;

FIG. 31 is a circuit diagram illustrating a configuration of an eighth embodiment of the invention;

FIG. 32 is a circuit diagram illustrating a configuration of a ninth embodiment of the invention;

FIG. 33 is a circuit diagram illustrating a configuration of a conventional circuit; and

FIG. 34 is a circuit diagram illustrating another configuration of a conventional circuit.

### DETAILED DESCRIPTION OF THE PREFERRED EMBODIMENTS

Embodiments of the invention will be described below with reference to the drawings.

### First Embodiment

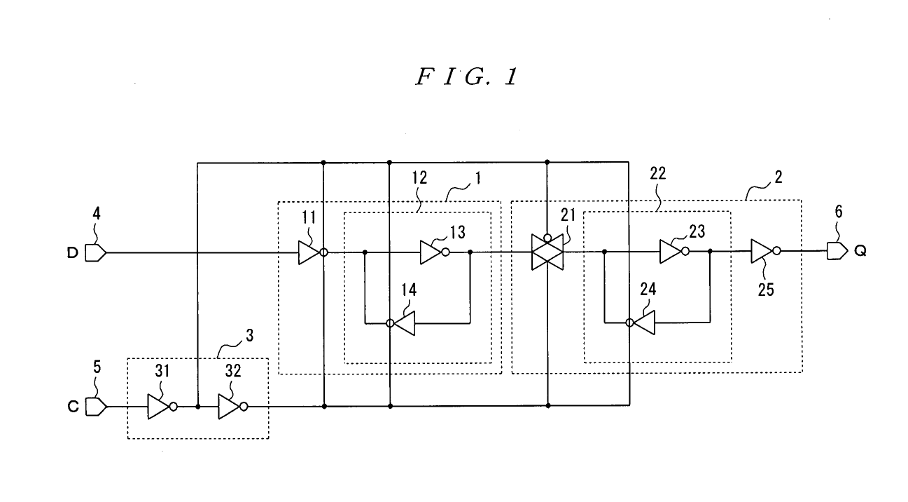

As illustrated in FIG. 1, a first embodiment related to a master-slave type flip-flop circuit of the invention comprises a master latch 1, a slave latch 2 and a clock supply circuit 3 supplying a clock thereto and is operated with a rise of the clock.

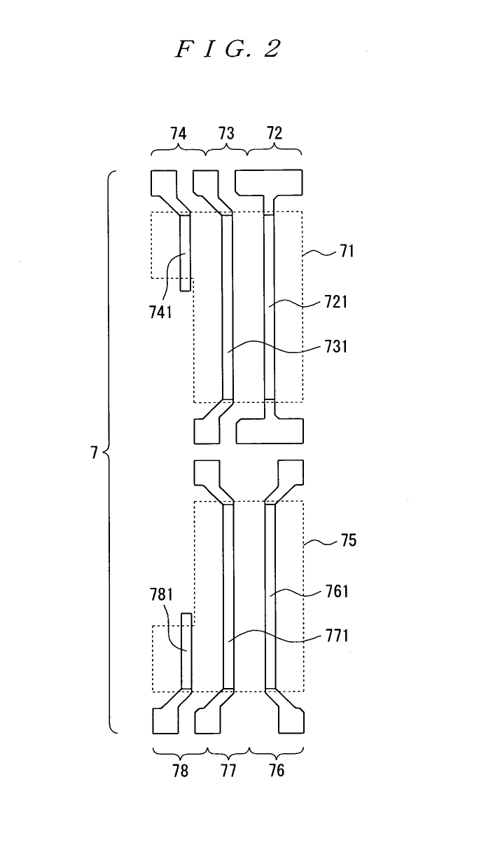

In addition, in that first embodiment, each component configuring those elements is configured with a basic cell, wherein that basic cell is made of six MOS transistors as illustrate in FIG. 2. Configuration of that basic cell will be described later.

A master latch 1 consists of a clocked inverter 11 and a latch circuit 12 in order to take in and retain data D being input to an input terminal 4. The latch circuit 12 configures a closed circuit with an inverter 13 and a clocked inverter 14 so as to be capable of retaining data.

The slave latch 2 takes in the data from the master latch 1 to retain and output those taken-in data. Therefore, the slave latch 2 consists of a transmission gate 21, a latch circuit 22 and an inverter 25. The latch circuit 22 configures a closed circuit with an inverter 23 and a clocked inverter 24 so as to be capable of retaining data. The data retained by that latch circuit 22 are output from an output terminal 6 through the inverter 25.

A clock supply circuit 3 consists of an inverter 31 receiving and inverting a clock C which is input to a clock terminal 5 and an inverter 32 inverting an output of the inverter 31 to obtain a clock C. The inverted clock /C inverted by the inverter 31 is supplied to the clocked inverters 11, 14 and 24 and to the transmission gate 21 respectively. Similarly, the clock C being output from the inverter 32 is supplied to the clocked inverters 11, 14 and 24 and to the transmission gate 21 respectively.

Accordingly, the clocked inverters 11, 14 and 24 and the transmission gate 21 functions as switches which are operated with a clock. When the clocked inverters 11 and 24 are on, the clocked inverter 14 and the transmission gate 21 are put off. On the contrary, when the clocked inverters 11 and 24 are off, the clocked inverter 14 and the transmission gate 21 are put on.

### (Configuration of Basic Cell)

Next, a configuration (layout) of a basic cell of an SOG (Sea Of Gate) configuring a gate array, to which the first embodiment is applied, will be described with reference to FIG. 2.

As illustrated in FIG. 2, a basic cell 7 is provided with an NMOS element region 71 and a PMOS element region 75 on a semiconductor substrate (not illustrated in the drawing) and consists of three N-type MOS transistors 72 to 74 being formed in the NMOS element region 71 and three P-type MOS transistors 76 to 78 being formed in the PMOS element region 75.

The MOS transistors 72 to 74 and the MOS transistors 76 to 78 are arranged to face each other in a predetermined gap as illustrated in the drawing. MOS transistors 72 to 74 are formed in a triplely arrayed manner and comprise gate electrodes 721, 731 and 741 respectively. Three of those MOS transistors 76 to 78 are formed in a triplely arrayed manner and comprise gate electrodes 761, 771 and 781 respectively.

As illustrated in FIG. 2, the triplely arrayed N-type MOS transistors 72 to 74 are configured by doubly arrayed main MOS transistors 72 and 73 with normal sizes and an auxiliary MOS transistor 74 with a size smaller than the normal size. Similarly, the triplely arrayed P-type MOS transistors 76 to 78 are configured by doubly arrayed main MOS transistors 76 and 77 with normal sizes and an auxiliary MOS transistor 78 with a size smaller than the normal size.

Here, the size (proportion of channel width W to channel length L (W/L)) of the auxiliary transistor 74 is preferably relatively smaller than the main MOS transistors 72 and 73 and preferably is sized, for example, to one third to two thirds of the size of the main MOS transistor. The size of the auxiliary MOS transistor 78 is likewise.

### (Specific Configuration of Each Part)

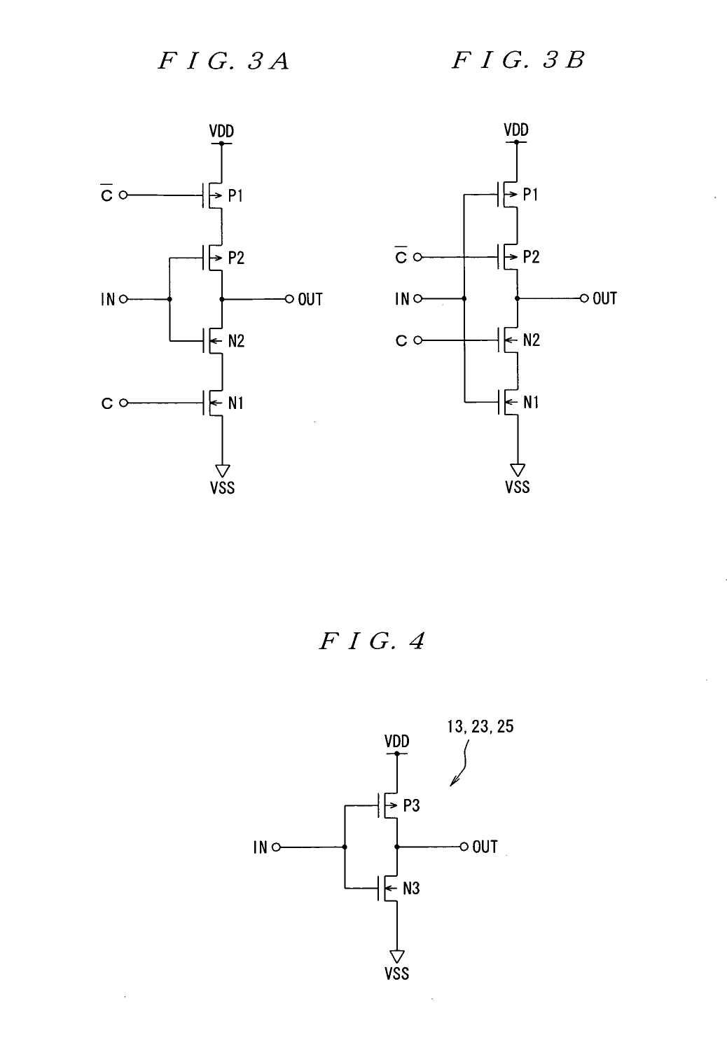

For a first embodiment, respective components configuring a master latch 1, a slave latch 2 and a clock supply circuit 3 are realized with MOS transistors of a basic cell 7 illustrated in FIG. 2. Therefore, the configuration example thereof will be described with reference to FIG. 3A to FIG. 8.

The clocked inverter 11 is adopted as a component of the master latch 1 in FIG. 1. A reason thereof is as follows.

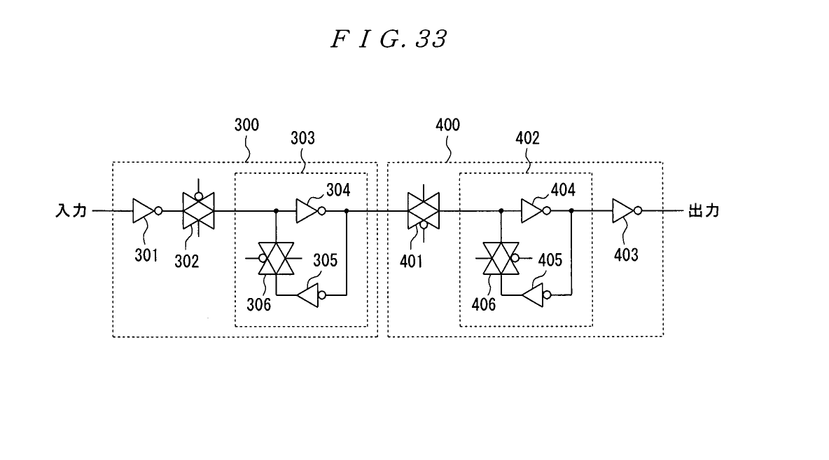

That is, as illustrated in FIG. 33, a clocked inverter is configured by the inverter 301 consisting of CMOS and the transmission gate 302. Then, a pass-through current possibly flows in the inverter 301 to occasionally cause destruction of the elements in the case where data D being input to an input terminal 4 becomes high impedance. In addition, due to constraint of layout, a configuration of the transmission gate 302 with the basic cell 7 gives rise to necessity for source electrodes and drain electrodes in the P-type and N-type MOS transistors establishing a pair for being mutually brought into connection.

In addition, configuration only with the transmission gate 302 is feasible without using the inverter 301 at the initial stage of the data D from the input terminal 4. In that case, the ON resistance of the MOS transistor configuring the transmission gate 302 might no longer enable transmission of the data D to the next stage in the case where the power supply voltage VDD is low.

Therefore, for the first embodiment, a clocked inverter is used as a component of the master latch 1 to, thereby, eliminate the above described failure.

The clocked inverter includes a first type illustrated in FIG. 3A and a second type illustrated in FIG. 3B. The first type consists of a CMOS inverter consisting of the N-type and P-type MOS transistors P2 and N2 and two switch elements consisting of the N-type and P-type MOS transistors P1 and N1. The second type consists of a CMOS inverter consisting of the N-type and P-type MOS transistors P1 and N1 and two switch elements consisting of the N-type and P-type MOS transistors P2 and N2.

For the first type, when the MOS transistor P1 having been put off with the clock is put on and is supplied with power supply, that MOS transistor P1 having been put on cannot drive a load to change the output unless ON resistance or parasite capacitance of the MOS transistor P2 is charged first.

On the other hand, for the second type, when the MOS transistor P2 having been put off with the clock is put on, a power supply voltage VDD is already applied to the MOS transistor P1 and, therefore, electric potential of the MOS transistor P1 is defined. Therefore, the MOS transistor P2 only has to drive a load and the delay time of the second type is shorter.

Therefore, a circuit of the second type in FIG. 3B is adopted for the clocked inverter 11 configuring the master latch 1 in FIG. 1.

That is, as illustrated in FIG. 3B, the clocked inverter 11 in FIG. 1 consists of an inverter (CMOS inverter) configured by the P-type MOS transistor P1 and the N-type MOS transistor N1 and a P-type MOS transistor P2 and NMOS transistor N2 being switch elements controlling ON-OFF on a logic of an output of that inverter. The gate electrodes of the MOS transistors P1 and N1 are brought into common connection and the common connection part is supplied with an input signal IN. The gate electrodes of the MOS transistors P2 and N2 are respectively supplied with the clocks C and /C.

The P-type and N-type MOS transistors P1 and N1 configuring the above described inverter is formed by using a pair among the main MOS transistors 72, 73, 76 and 77 of the basic cell 7 in FIG. 2. The P-type and N-type MOS transistors P2 and N2 configuring the switch element are formed by using the auxiliary MOS transistors 74 and 78 of that same basic cell 7.

As illustrated in FIG. 4, the inverter 13 configuring the latch circuit 12 in FIG. 1 is configured by the P-type MOS transistor P3 and the N-type MOS transistor N3. The P-type and N-type MOS transistors P3 and N3 configuring that inverter are formed by using a pair among the main MOS transistors 72, 73, 76 and 77 of the basic cell 7 in FIG. 2. The reason why the main MOS transistors are used is that the inverter 13 is on a data propagation path from the input terminal 4 to reach the output terminal 6 as illustrated in FIG. 1.

As illustrated in FIG. 5, the clocked inverter 14 configuring the latch circuit 12 in FIG. 1 consists of an inverter configured by the P-type MOS transistor P4 and the N-type MOS transistor N4 and the P-type MOS transistor P5 and the NMOS transistor N5 being switch elements controlling ON-OFF between this inverter and the power supplies VDD and VSS. The gate electrodes of the MOS transistors P4 and N4 are brought into common connection and the common connection part is supplied with an input signal IN. The gate electrodes of the MOS transistors P5 and N5 are respectively supplied with the clocks C and /C.

The reason why a circuit as in FIG. 5 is adopted for the clocked inverter 14 is that the clocked inverter 14 configures the wired OR logic with the clocked inverter 11. Therefore, for the clocked inverter 14, a circuit illustrated in FIG. 5 which expands delay on the contrary to the clocked inverter 11 is adopted.

The P-type and N-type MOS transistors P4 and N5 configuring the above described inverter are formed by using a pair among the main MOS transistors 72, 73, 76 and 77 of the basic cell 7 in FIG. 2. The P-type and N-type MOS transistors P5 and N5 configuring the switch element are formed by using the auxiliary MOS transistors 74 and 78 of that same basic cell 7.

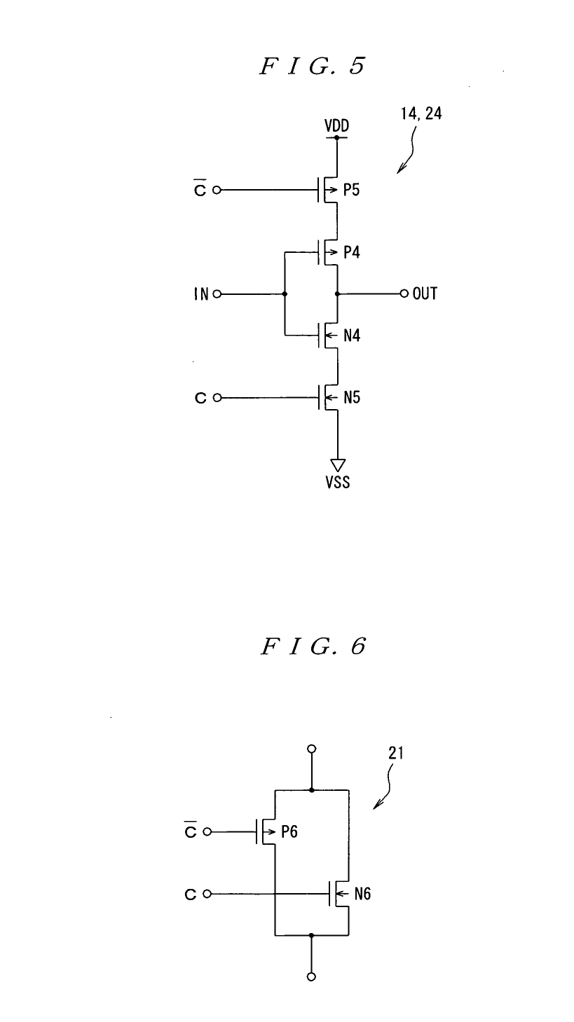

As illustrated in FIG. 6, the transmission gate 21 in FIG. 1 consists of the P-type MOS transistor P6 and the N-type MOS transistor N6, which are brought into connection in parallel. The gate electrodes of the MOS transistors P6 and N6 are respectively supplied with the clocks C and /C. The P-type and N-type MOS transistors P6 and N6 configuring the transmission gate 21 is formed by using a pair among the main MOS transistors 72, 73, 76 and 77 of the basic cell 7 in FIG. 2. The reason why the main MOS transistors are used thus is that the transmission gate 21 is on a data propagation path from the input terminal 4 to reach the output terminal 6 as illustrated in FIG. 1.

The inverter 23 and the inverter 25 configuring the latch circuit 22 in FIG. 1 are configured likewise the inverter 13 illustrated in FIG. 1 and FIG. 4 respectively. The reason thereof is that the inverters 23 and 25 are on a data propagation path from the input terminal 4 to reach the output terminal 6 likewise the inverter 13 (see FIG. 1).

The clocked inverter 24 configuring the latch circuit 22 in FIG. 1 is configured likewise the inverter 14 illustrated in FIG. 1 and FIG. 5. The reason thereof is that the clocked inverter 24 configures the wired OR logic with the transmission gate 21. Therefore, for the clocked inverter 24, a circuit illustrated in FIG. 5 which expands delay on the contrary to the clocked inverter 11 is adopted.

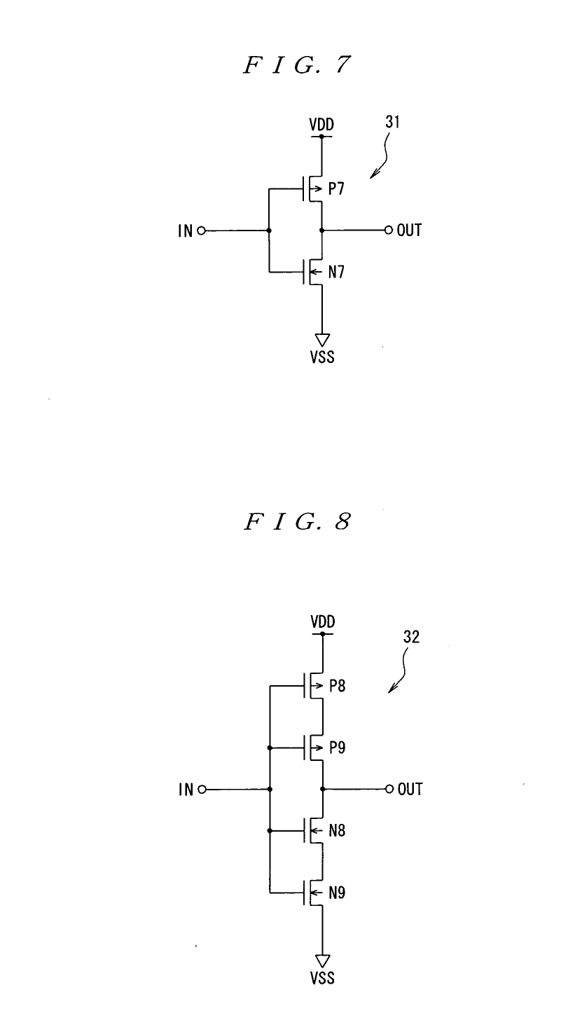

As illustrated in FIG. 7, the inverter 31 is configured by the P-type MOS transistor P7 and the N-type MOS transistor N7. Those P-type and N-type MOS transistors P7 and N7 are formed by using the auxiliary MOS transistors 74 and 78 of the basic cell 7 in FIG. 2.

The reason why the inverter 31 is formed thus by using the auxiliary MOS transistors 74 and 78 of the basic cell 7 is as follows. That is, the gate capacity of the inverter 31 undergoes buffering as a clock line at the occasion of a layout on a chip level and, therefore, its transistor size is preferably smaller.

As illustrated in FIG. 8, the inverter 32 in FIG. 1 is configured by bringing the P-type MOS transistors P8 and P9 and the N-type MOS transistors N8 and N9 into cascade connection. The MOS transistors P8, P9, N8 and N9 configuring that inverter are formed by using the main MOS transistors 72, 73, 76 and 77 of the basic cell 7 in FIG. 2.

The reason why the inverter 32 is formed thus is as follows. That is, the inverter 32 is a necessary logic circuit for configuring a circuit. However, although a small-sized MOS transistor is sufficient in consideration of Fan Out and the pass-through current amount, the auxiliary MOS transistors 74 and 78 of the basic cell 7 forming the inverter 31 cannot be used.

Therefore, for the inverter 32, the main MOS transistors 72, 73, 76 and 77 of the basic cell 7 are brought into cascade connection to configure a CMOS inverter so that a circuit equivalent to the CMOS inverter with the auxiliary MOS transistors 74 and 78 is obtained. Thereby, the inverters 31 and 32 can be formed with the same basic cell 7 and can utilize the basic cell 7 effectively.

(Specific Configuration with Gate Array)

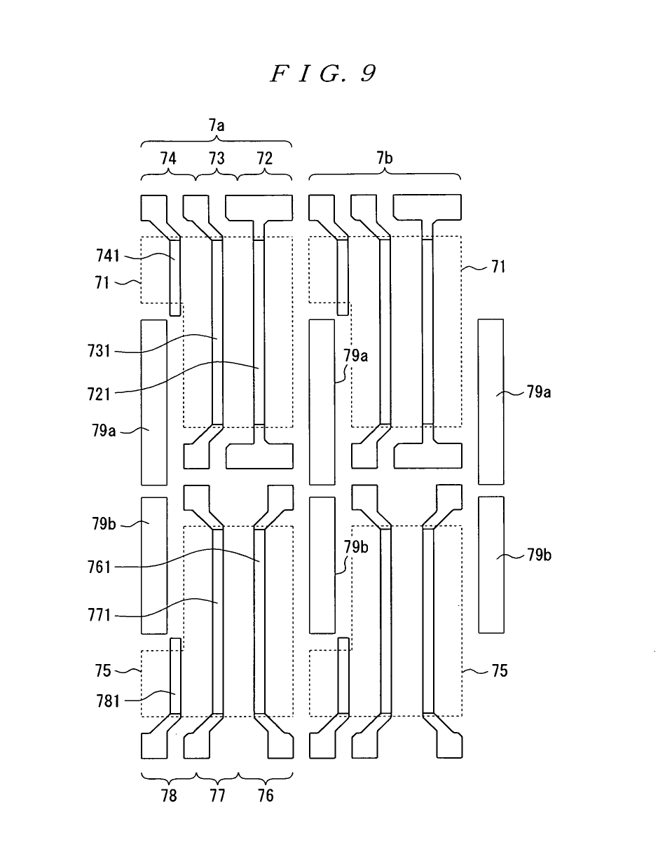

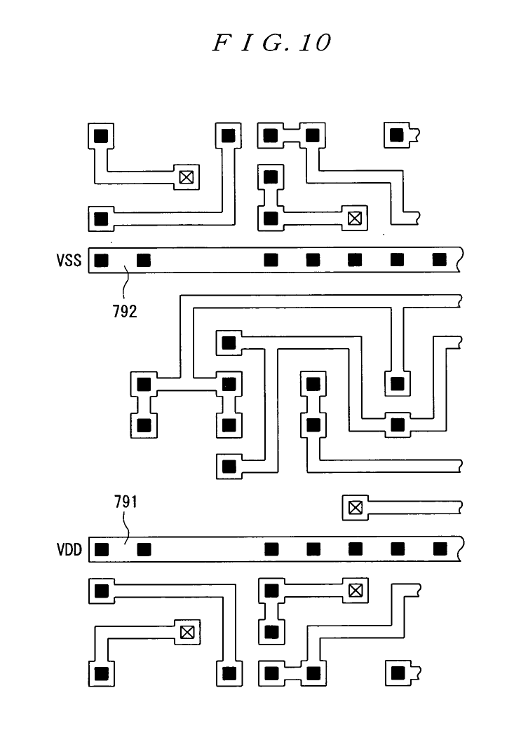

A first embodiment is configured by a gate array including the basic cell 7 in FIG. 2. Therefore, a configuration example thereof will be described with reference to FIG. 9 to FIG. 11.

FIG. 9 exemplifies a layout of the gate array to which this first embodiment is applied. As illustrated in the drawing, the gate array hereof includes the same great number of basic cells 7a, 7b and so on as the basic cell 7 in FIG. 2 on a semiconductor substrate (not illustrated in the drawing) being arranged regularly. In this example, two basic cells 7a and 7b are arranged. Stoppers 79a and 79b for splitting the basic cells electrically are arranged respectively on the left and the right of the basic cells 7a and 7b as illustrated in the drawing.

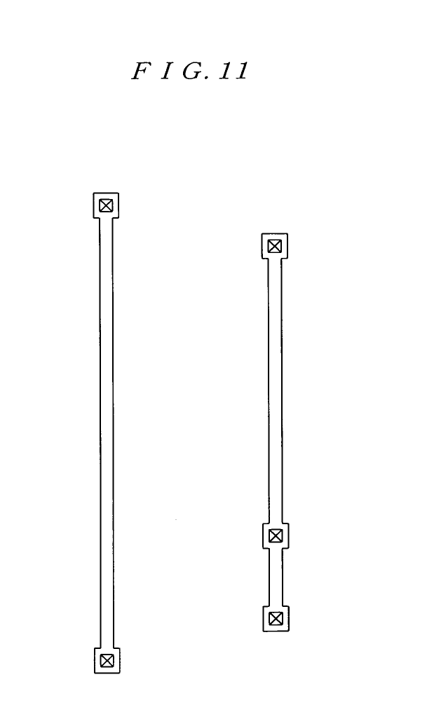

FIG. 10 is a plan diagram exemplifying the wiring on the first layer being formed through an insulator on the configuration in FIG. 9. The respective wiring pattern of that first layer is brought into electrical connection to the respective parts illustrated in FIG. 9 through contact holes marked by black quadrangles. In addition, predetermined wiring patterns of the first layer in FIG. 10 are brought into electrical connection to the wiring patterns in FIG. 11 through contact holes illustrated by quadrangles including X marks therein.

On the first layer in FIG. 10, for example, as illustrated in the drawing, a wiring pattern 791 supplied with power supply voltage VDD and a wiring pattern 792 provided with a ground voltage VSS are arranged. The wiring pattern 791 is brought into electrical connection to a stopper 79b and the like in FIG. 9 through the contact holes. In addition, the wiring pattern 792 is brought into electrical connection to a stopper 79a and the like in FIG. 9 through the contact holes.

FIG. 11 is a plan diagram exemplifying wiring on the second layer being formed on the second layer in FIG. 10 through an insulator. On that second layer, wiring patterns in the vertical direction as illustrated in the drawing are arranged. Those wiring patterns are brought into electrical connection to a predetermined wiring patterns on the first layer in FIG. 10 through the contact holes indicated with quadrangles including x symbols.

As described above, in the first embodiment, a master-slave type flip-flop is configured with a gate array. As illustrated in FIG. 2, the basic cell of that gate array consisting of four main MOS transistors and two auxiliary MOS transistors is used. Moreover, the logic circuits of respective parts configuring the flip-flop are configured by combining those six MOS transistors so as to become optimum according to applications and functions thereof.

Therefore, according to the first embodiment, reduction in power consumption and reduction in EMI can be planned. In addition, according to the first embodiment, the basic cell can be utilized effectively at the occasion of forming respective types of logic circuits and wiring resource can be secured to plan simplification of wiring.

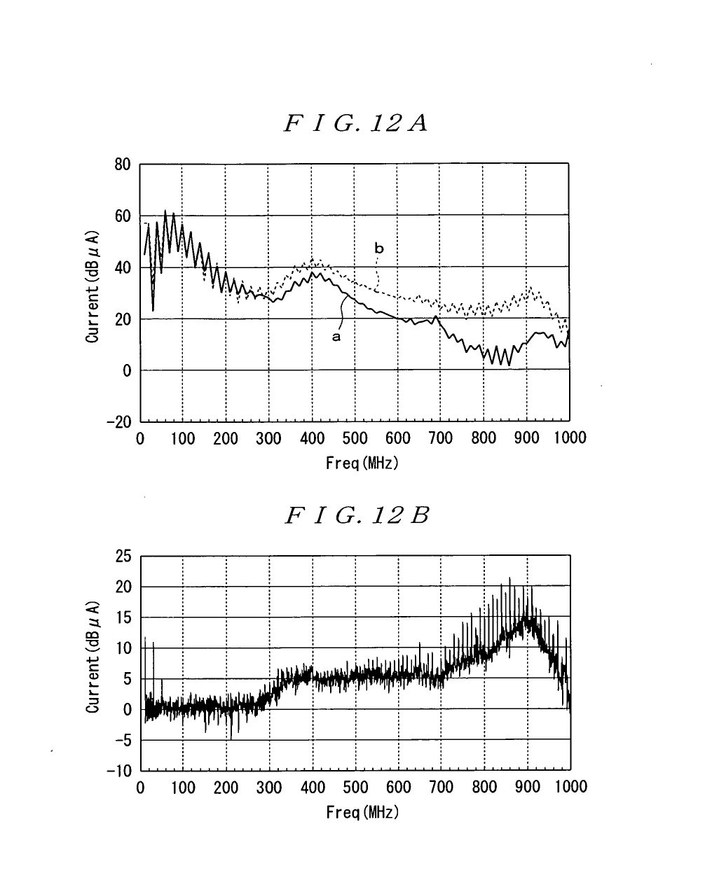

Next, in order to confirm specific effects of reduction in EMI in the first embodiment, the first embodiment and the conventional flip-flop (conventional circuit) illustrated in FIG. 33 have undergone measurement on the frequency component of noise included in a power supply current respectively. Therefore, a measurement result thereof is illustrated in FIGS. 12A and 12B.

FIG. 12A illustrates measurement results thereof, where a curb a plots noise of the power supply current of the first embodiment and a curb b plots noise of the power supply current of a conventional circuit. FIG. 12B indicates the difference of the both cases.

According to FIGS. 12A and 12B, it is apparent that the noise of the power supply current decreases in a region where frequency is not less than 300 MHz in the first embodiment compared with the conventional circuit. In addition, according to FIG. 12B, the maximum effect is obtained in the vicinity of 900 MHz in frequency.

### Second Embodiment

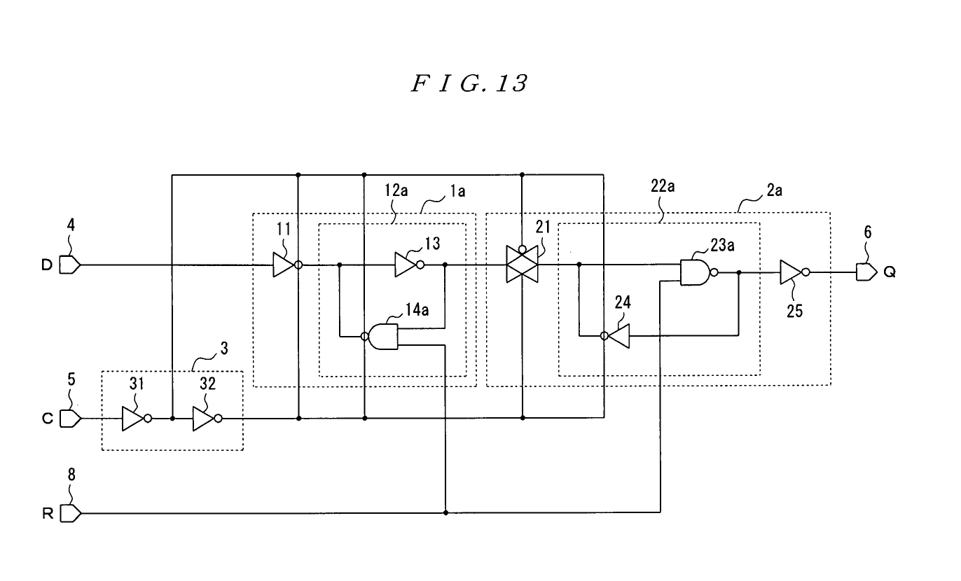

As illustrated in FIG. 13, a second embodiment related to a master-slave type flip-flop circuit of the invention comprises a master latch 1a, a slave latch 2a and a clock supply circuit 3 supplying a clock thereto; is operated with a rise of the clock; and has a reset (clear) function.

That is, the second embodiment is basically configured likewise the first embodiment illustrated in FIG. 1 and the master latch 1 and the slave latch 2 in FIG. 1 are replaced by the master latch 1a and the slave latch 2a.

Here, the second embodiment is basically configured likewise the first embodiment. Therefore, like reference numerals and characters designate the same components so that description thereon is omitted as much as possible.

A master latch 1a consists of a clocked inverter 11 and a latch circuit 12a so as to be capable of taking in and retaining data D being input to an input terminal 4 according to a logic of a clock C being input to a clock terminal 5 and resetting a state inside the master latch with a reset signal R being input to a reset terminal 8 irrespective of the logic of the clock C being input to the clock terminal 5. The latch circuit 12a configures a closed circuit with an inverter 13 and clocked NAND gate 14a with two inputs so as to be capable of taking in and retaining data. In addition, in order to reset the state inside the master latch, a reset signal R is input to an input terminal of the clocked NAND gate 14a.

A slave latch 2a takes in and retains data from the master latch 1a according to the logic of the clock C being input to the clock terminal 5 and outputs the data to an output terminal 6. In addition, the slave latch 2a resets a state inside the slave latch with a reset signal R irrespective of the logic of the clock C being input to the clock terminal 5. Therefore, the slave latch 2a consists of a transmission gate 21, a latch circuit 22a and an inverter 25. The latch circuit 22a configures a closed circuit with a NAND gate 23a with two inputs and a clocked inverter 24 so as to be capable of taking in and retaining data from the master latch 1a. In addition, in order to reset the state inside the slave latch, the reset signal R is input to the input terminal of the NAND gate 23a. The data retained by the latch circuit 22a are output from an output terminal 6 through the inverter 25.

The inverted clock /C inverted by the inverter 31 and the clock C being output from the inverter 32 are supplied to the clocked inverters 11 and 24, clocked NAND gate 14a and the transmission gate 21 respectively.

Next, for a second embodiment, respective components configuring a master latch 1a, a slave latch 2a and a clock supply circuit 3 are realized with MOS transistors of a basic cell 7 illustrated in FIG. 2. Therefore, the configuration example thereof will be described.

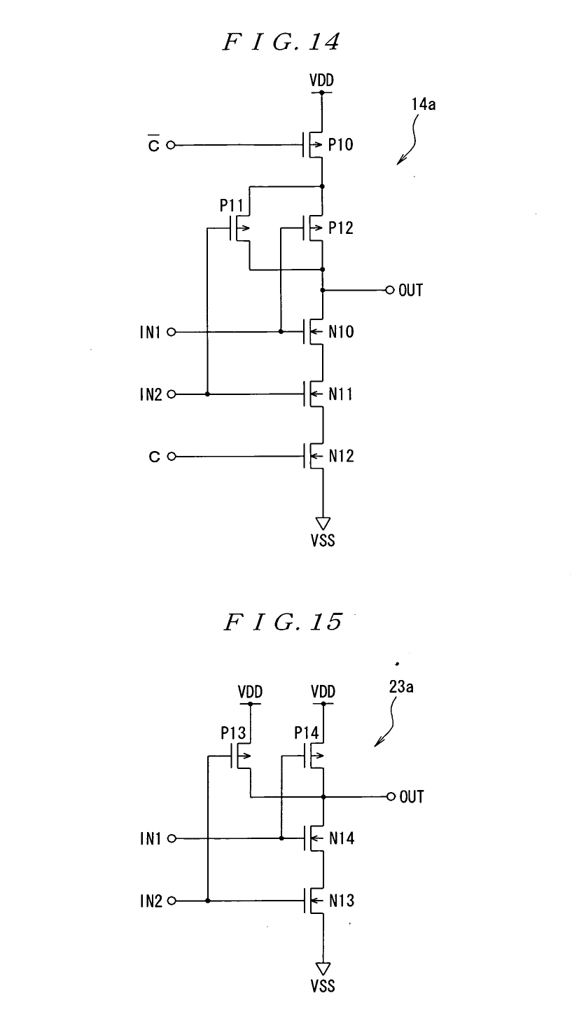

Comparing the configuration of the second embodiment with the configuration of the first embodiment in FIG. 1, configurations of the clocked inverter 14a and the NAND gate 23a are different and are configured as in FIG. 14 and FIG. 15. Here, a configuration of another portion is the same as the configuration of the first embodiment and therefore description thereon will be omitted.

As illustrated in FIG. 14, the clocked NAND gate 14a comprises NAND gate consisting of the P-type MOS transistors P11 and P12 brought into connection in parallel and the N-type MOS transistors N10 and N11 brought into cascade connection and, moreover, comprises the P-type MOS transistor P10 and the N-type MOS transistor N12 being switch elements controlling ON-OFF between that NAND gate and the power supplies VDD and VSS.

An input signal IN1 is input to the respective gate electrodes of the MOS transistors P12 and N10 configuring the NAND gate and an input signal IN2 is input to the respective gate electrodes of the MOS transistors P11 and N11. The gate electrodes of the MOS transistors P10 and N12 are respectively supplied with the clocks C and /C.

The reason why a circuit provided with the MOS transistors P10 and N12 on the side of the power supply is adopted for the clocked NAND gate 14a as illustrated in FIG. 14 is as follows. That is, the clocked NAND gate 14a configures the wired OR logic with the clocked inverter 11. Therefore, for the clocked NAND gate 14a, a circuit illustrated in FIG. 14 which expands delay on the contrary to the clocked inverter 11 is adopted.

For the clocked NAND gate 14, the P-type MOS transistors P11 and P12 and the N-type MOS transistors N10 and N11 configuring the NAND gate are formed by using the main MOS transistors 72, 73, 76 and 77 of the basic cell 7 in FIG. 2. The P-type and N-type MOS transistors P10 and N12 configuring the switch element are formed by using the auxiliary MOS transistors 74 and 78 of that same basic cell 7. Accordingly, the clocked NAND gate 14a in FIG. 14 can be configured only by the basic cell 7 in FIG. 2.

As illustrated in FIG. 15, the NAND gate 23a consists of P-type MOS transistors P13 and P14 brought into combination in parallel and the N-type MOS transistors N13 and N14 brought into cascade combination. A reset signal R is input as the input signal IN1 to the respective gate electrodes of the MOS transistors P14 and N14. Data are input as the input signal IN2 to the respective gate electrodes of the MOS transistors P13 and N14.

In addition, the NAND gate 23a is on a propagation path from the input terminal 4 to reach the output terminal 6 as illustrated in FIGS. 12A and 12B and data are input thereto. Therefore, the MOS transistors P13 and N14 to which data are input are formed by using a pair among the main MOS transistors 72, 73, 76 and 77 of the basic cell 7 in FIG. 2. In addition, the reset signal R is input to the NAND gate 23a and the reset signal line thereof undergoes buffering. Therefore, a smaller MOS transistor is preferable. Therefore, the MOS transistors P14 and N14 to which the reset signal R is input are formed by using the auxiliary MOS transistors 74 and 78 of that same basic cell 7.

According to the second embodiment described above, a reset signal can reset data and, moreover, the effect likewise the first embodiment can be realized.

### Third Embodiment

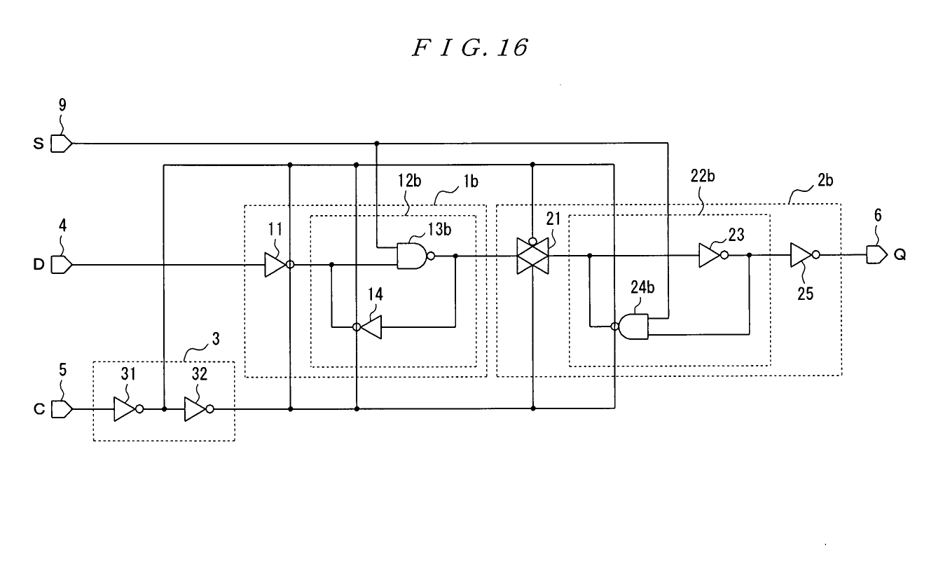

As illustrated in FIG. 16, a third embodiment related to a master-slave type flip-flop circuit of the invention comprises a master latch 1b, a slave latch 2b and a clock supply circuit 3 supplying a clock thereto; is operated with a rise of the clock; and has a set function.

That is, the third embodiment is basically configured likewise the first embodiment illustrated in FIG. 1 and the master latch 1 and the slave latch 2 in FIG. 1 are replaced by the master latch 1b and the slave latch 2b.

Here, the third embodiment is basically configured likewise the first embodiment. Therefore, like reference numerals and characters designate the same components so that description thereon is omitted as much as possible.

A master latch 1b consists of a clocked inverter 11 and a latch circuit 12b so as to be capable of taking in and retaining data D being input to an input terminal 4 according to a logic of the clock C being input to a clock terminal 5 and setting a state inside the master latch with a set signal S being input to a set terminal 9 irrespective of the logic of the clock C being input to the clock terminal 5. The latch circuit 12b configures a closed circuit with NAND gate 13b with two inputs and a clocked inverter 14 so as to be capable of retaining data. In addition, in order to set the data, a set signal S is input to an input terminal of the NAND gate 13b.

A slave latch 2b takes in and retains data from the master latch 1b according to the logic of the clock C being input to the clock terminal 5 and outputs the data to an output terminal 6. In addition, the slave latch 2b sets the state inside the slave latch with a set signal S irrespective of the logic of the clock C being input to the clock terminal 5. Therefore, the slave latch 2b consists of a transmission gate 21, a latch circuit 22b and an inverter 25. The latch circuit 22b configures a closed circuit with an inverter 23 and a clocked NAND gate 24b with two inputs so as to be capable of retaining data. In addition, in order to set the data, the set signal S is input to the input terminal of the clocked NAND gate 24b. The data retained by the latch circuit 22b are output from an output terminal 6 through the inverter 25.

The inverted clock /C inverted by the inverter 31 and the clock C being output from the inverter 32 are supplied to the clocked inverters 11 and 14, clocked NAND gate 24b and the transmission gate 21 respectively.

Next, for a third embodiment, respective components configuring a master latch 1b, a slave latch 2b and a clock supply circuit 3 are realized with MOS transistors of a basic cell 7 illustrated in FIG. 2. Therefore, the configuration example thereof will be described.

Comparing the configuration of the third embodiment with the configuration of the first embodiment in FIG. 1, configurations of the NAND gate 13b and the clocked NAND gate 24b are different and configurations of the other portions are the same as the configuration of the first embodiment and, therefore, description thereon will be omitted.

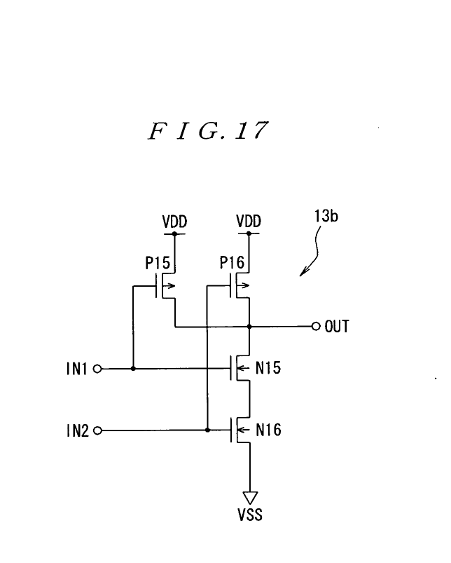

As illustrated in FIG. 17, the NAND gate 13b consists of the P-type MOS transistors P15 and P16 brought into connection in parallel and the N-type MOS transistors N15 and N16 brought into cascade connection. Data are input to the respective gate electrodes of the MOS transistors P15 and N15 as an input signal IN1. A set signal S is input to the respective gate electrodes of the MOS transistors P16 and N16 as the input signal IN2.

In addition, the NAND gate 13b is on a data propagation path from the input terminal 4 to reach the output terminal 6 as illustrated in FIG. 17 and data are input thereto. Therefore, the MOS transistors P15 and N15 to which data are input are formed by using a pair among the main MOS transistors 72, 73, 76 and 77 of the basic cell 7 in FIG. 2. In addition, the set signal S is input to the NAND gate 13b and the set signal line thereof undergoes buffering. Therefore, a smaller MOS transistor is preferable. Therefore, the MOS transistors P16 and N16 to which the set signal S is input are formed by using the auxiliary MOS transistors 74 and 78 of that same basic cell 7.

The clocked NAND gate 24b is designed to be configured likewise the clocked NAND gate 14a illustrated in FIG. 14.

According to the third embodiment described above, a set signal can set data and, moreover, the effect likewise the first embodiment can be realized.

### Fourth Embodiment

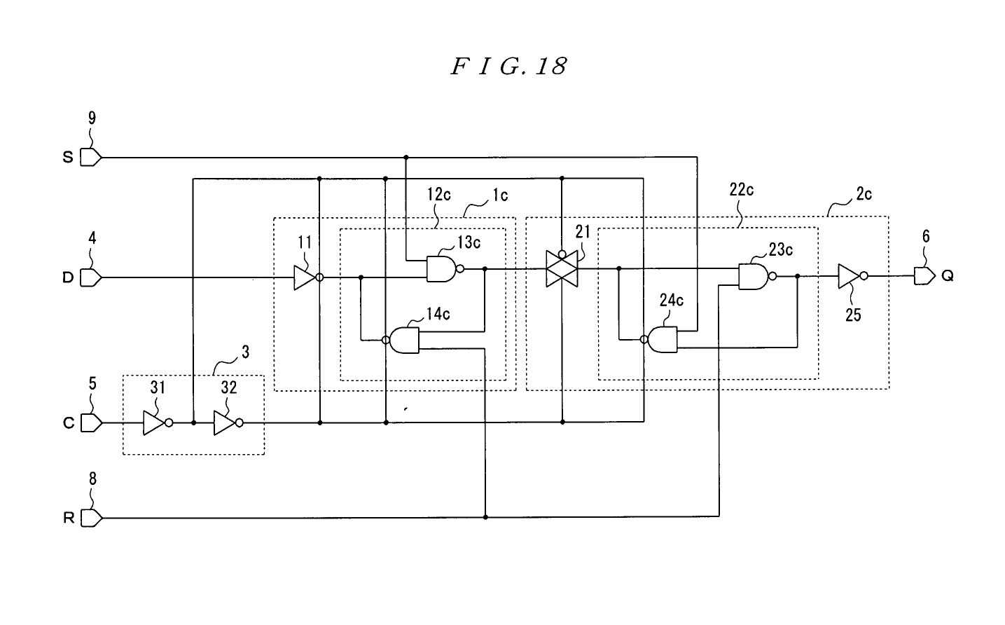

As illustrated in FIG. 18, a fourth embodiment related to a master-slave type flip-flop circuit of the invention comprises a master latch 1c, a slave latch 2c and a clock supply circuit 3 supplying a clock thereto; is operated with a rise of the clock; and has a set and reset functions.

That is, the fourth embodiment is basically configured likewise the first embodiment illustrated in FIG. 1 and the master latch 1 and the slave latch 2 in FIG. 1 are replaced by the master latch 1c and the slave latch 2c.

Here, the fourth embodiment is basically configured likewise the first embodiment. Therefore, like reference numerals and characters designate the same components so that description thereon is omitted as much as possible.

A master latch 1c is designed to take in and retain data D being input to an input terminal 4 according to a logic of the clock C being input to a clock terminal 5 so as to be capable of setting a state inside the master latch with a set signal S being input to a set terminal 9 irrespective of the logic of the clock C being input to the clock terminal 5 and resetting the state inside the master latch with the reset signal R being input to the reset terminal 8 according to the logic of the clock C being input to the clock terminal 5.

Therefore, the master latch 1c consists of a clocked inverter 11 and a latch circuit 12c. The latch circuit 12c configures a closed circuit with a NAND gate 13c with two inputs and a clocked NAND gate 14c with two inputs so as to be capable of retaining data. In addition, in order to set the data, the set signal S is input to the input terminal of the NAND gate 13c. Moreover, in order to reset the data, a reset signal R is input to an input terminal of the clocked NAND gate 14c.

A slave latch 2c takes in and retains data from the master latch 1c according to a logic of the clock C being input to the clock terminal 5 and outputs the data to an output terminal 6. The slave latch 2c is designed to be capable of setting the state inside the slave latch with a set signal S irrespective of the logic of the clock C being input to the clock terminal 5 and capable of resetting the state inside the slave latch with the reset signal R irrespective of the logic of the clock C being input to the clock terminal 5.

Therefore, the slave latch 2c consists of a transmission gate 21, a latch circuit 22c and an inverter 25. The latch circuit 22c configures a closed circuit with a NAND gate 23c with two inputs and a clocked NAND gate 24c with two inputs so as to be capable of retaining data. In addition, in order to set the data, the set signal S is input to the input terminal of the clocked NAND gate 24c. Moreover, in order to reset the data, the reset signal R is input to the input terminal of the NAND gate 23c.

The inverted clock /C inverted by the inverter 31 and the clock C being output from the inverter 32 are supplied to the clocked inverter 11, clocked NAND gates 14c and 24c and the transmission gate 21 respectively.

Next, for a fourth embodiment, respective components configuring a master latch 1c, a slave latch 2c and a clock supply circuit 3 are realized with MOS transistors of a basic cell 7 illustrated in FIG. 2. Therefore, the configuration example thereof will be described.

Comparing the configuration of the fourth embodiment with the configuration of the first embodiment in FIG. 1, configurations of the NAND gates 13c and 23c and the clocked NAND gates 14c and 24c are different and configurations of the other portions are the same as the configuration of the first embodiment and, therefore, description thereon will be omitted.

The NAND gate 13c is configured likewise the NAND gate 13b in FIG. 16 and FIG. 17. The NAND gate 23c is configured likewise the NAND gate 23a in FIG. 13 and FIG. 15. The clocked NAND gates 14c and 24c are configured likewise the clocked NAND gate 14a in FIG. 13 and FIG. 14.

According to the fourth embodiment described above, a set signal can set data and a reset signal can reset data and, moreover, the effect likewise the first embodiment can be realized.

### Fifth Embodiment

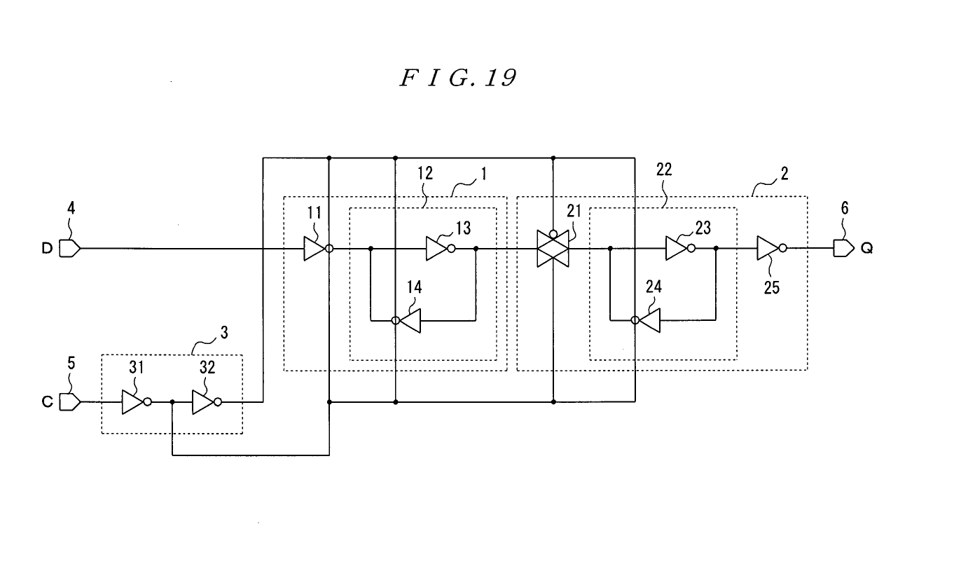

As illustrated in FIG. 19, a fifth embodiment related to a master-slave type flip-flop circuit of the invention comprises a master latch 1, a slave latch 2 and a clock supply circuit 3 supplying a clock thereto and is operated with a fall of the clock.

That is, the fifth embodiment is basically configured likewise the first embodiment illustrated in FIG. 1 and a destination supplied with the clock being output from the clock supply circuit 3 is changed as in FIG. 19 from FIG. 1 so that the master latch 1 and the slave latch 2 are operated with a fall of the clock.

Here, the respective second to fourth embodiments described above are operated with a rise of the clock but can be operated with a fall of the clock. In that case, the destination supplied with the clock being output from the clock supply circuit 3 can be changed likewise the fifth embodiment.

### Sixth Embodiment

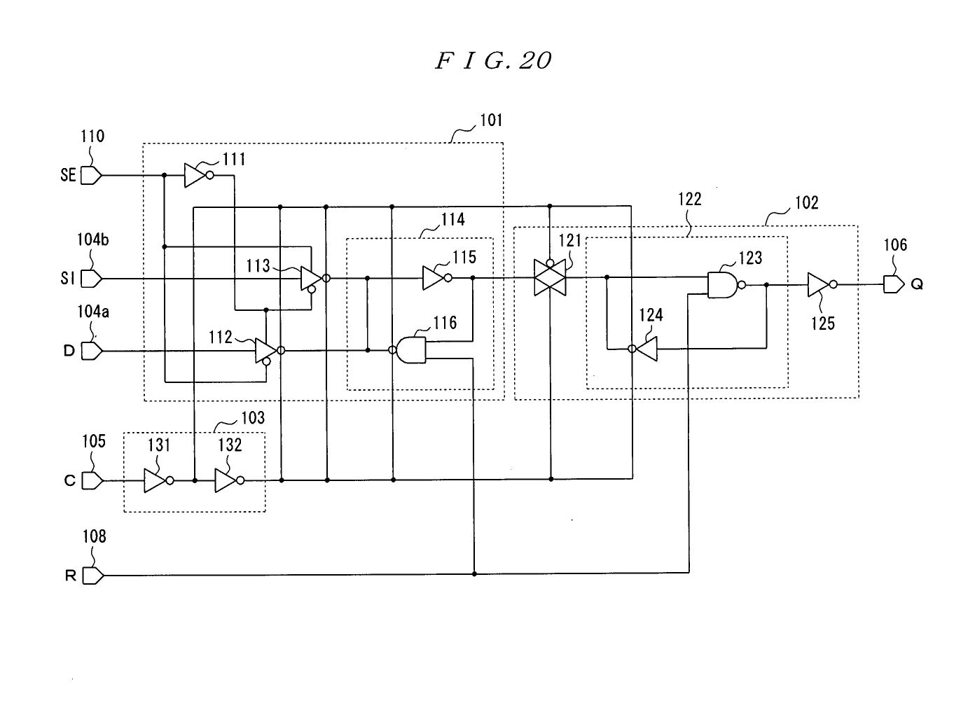

As illustrated in FIG. 20, a sixth embodiment related to a master-slave type flip-flop circuit of the invention comprises a master latch 101, a slave latch 102 and a clock supply circuit 103 supplying a clock thereto; is operated with a rise of the clock; and has a reset (clear) function.

In addition, the sixth embodiment is applicable to scan design being one of test simplification designing of an integrated circuit and can take in and retain the scan data at the time of a test operation and can take in and retain data at the time of a normal operation.

Moreover, for the sixth embodiment, respective components configuring a master latch 101, a slave latch 102 and a clock supply circuit 103 are configured by a basic cell, wherein that basic cell consists of six MOS transistors as illustrated in FIG. 2. Since FIG. 2 has already been described, description thereon will be omitted.

The sixth embodiment is configured by a gate array including the basic cell 7 in FIG. 2. A layout example of that gate array is as in FIG. 9 to FIG. 11. Since FIG. 9 to FIG. 11 have already been described, description thereon will be omitted.

The master latch 101 inputs data D supplied to the input terminal 104a at the time of a normal operation; inputs scan data SI supplied to the input terminal 104b at the time of a test operation; and takes in and retains the input data according to a logic of the clock C being input to the clock terminal 105. In addition, the reset signal R being input to the reset terminal 8 resets a state inside the master latch 101 irrespective of the logic of the clock C being input to the clock terminal 105. Therefore, the master latch 101 consists of an inverter 111, enabled clocked inverters 112 and 113 and a latch circuit 114.

The enabled clocked inverters 112 and 113 selectively inputs data D being input to the input terminal 104a and scan data SI being input to the input terminal 104b with a scan enable signal SE being input to a scan enable signal input terminal 110 and a signal subjected to logic inversion on this scan enable signal SE with the inverter 111.

The latch circuit 114 configures a closed circuit with an inverter 115 and a clocked NAND gate 116 with two inputs so as to be capable of taking in and retaining data. In addition, in order to reset a state inside the master latch 101, a reset signal R is input to an input terminal of the clocked NAND gate 116.

A slave latch 102 takes in and retains data from the master latch 101 according to a logic of the clock C being input to the clock terminal 105 and outputs the data to an output terminal 6. The slave latch 102 resets the state inside the slave latch with a reset signal R irrespective of the logic of the clock C being input to the clock terminal 105. Therefore, the slave latch 102 consists of a transmission gate 121, a latch circuit 122 and an inverter 125.

The latch circuit 122 configures a closed circuit with a NAND gate 123 with two inputs and a clocked inverter 124 so as to be capable of taking in and retaining data from the master latch 101. In addition, in order to reset the state inside the slave latch 102, the reset signal R is input to the input terminal of the NAND gate 123. The data retained by the latch circuit 122 are output from an output terminal 106 through the inverter 125.

The clock supply circuit 103 consists of an inverter 131 receiving and inverting a clock C being input to the clock terminal 105 and an inverter 132 inverting the output of the inverter 131 to obtain a clock C. The inverted clock /C inverted by the inverter 131 is supplied to the enabled clocked inverters 112 and 113, the clocked NAND gate 116, the transmission gate 121 and the clocked inverter 124 respectively. Similarly, the clock C being output from the inverter 132 is supplied to the enabled clocked inverters 112 and 113, the clocked NAND gate 116, the transmission gate 121 and the clocked inverter 124 respectively.

Accordingly, the clocked NAND gate 116, the transmission gate 121, the clocked inverter 124 respectively function as a switch being operated with a clock. In addition, the enabled clocked inverters 112 and 113 respectively function as a switch being operated with a clock and a scan enable signal SE.

Therefore, for example, when the enabled clocked inverter 112 and the clocked inverter 124 are on, the clocked NAND gate 116 and the transmission gate 121 are put off. On the contrary, when the enabled clocked inverter 112 and the clocked inverter 124 are off, the clocked NAND gate 116 and the transmission gate 121 are put on.

### (Specific Configuration of Each Part)

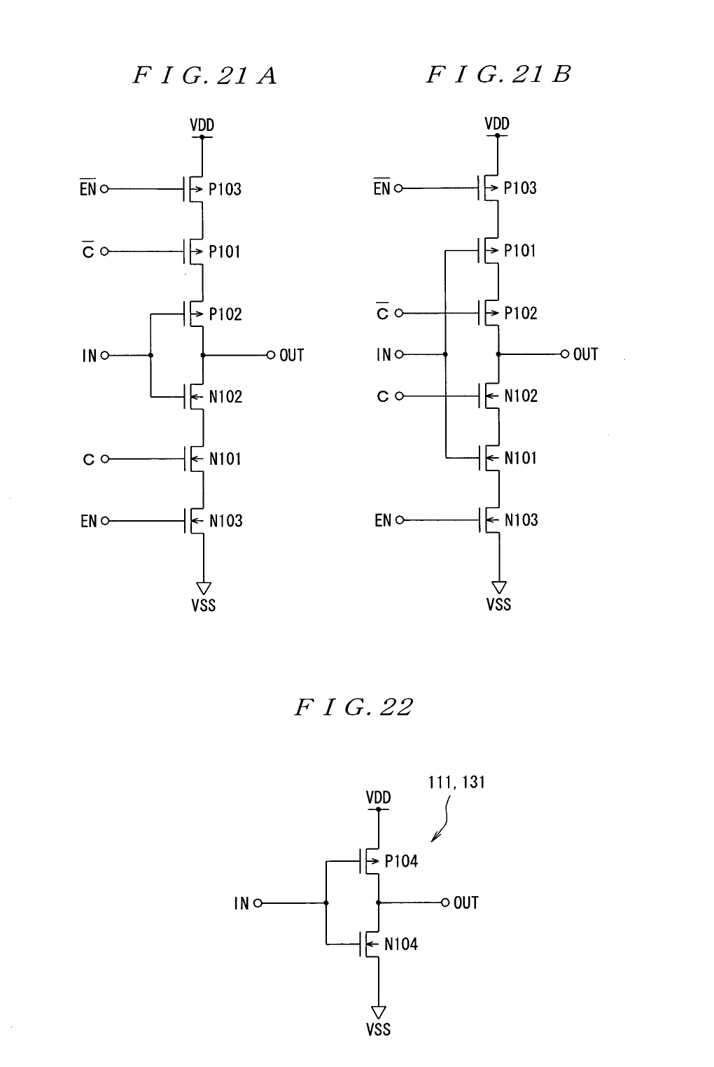

For a sixth embodiment, respective components configuring a master latch 101, a slave latch 102 and a clock supply circuit 103 are realized with MOS transistors of a basic cell 7 illustrated in FIG. 2. Therefore, the configuration example thereof will be described with reference to FIG. 21A to FIG. 28.

The enabled clocked inverter 112 and 113 are adopted as components of the master latch 101 in FIG. 20. A reason thereof is as follows.

That is, an enabled clocked inverter is configured by the logic circuit (such as inverter) consisting of CMOS and the transmission gate. Then, a pass-through current possibly flows in the inverter to occasionally cause destruction of the elements in the case where data D being input to an input terminal 104a becomes high impedance. In addition, due to constraint of layout, a configuration of the transmission gate with the basic cell 7 illustrated in FIG. 2 gives rise to necessity for source electrodes and drain electrodes in the P-type and N-type MOS transistors establishing a pair for being mutually brought into connection.

In addition, configuration only with two stages of the transmission gates is feasible without using the logic circuit at the initial stage of the data D from the input terminal 104a. In that case, the ON resistance of the MOS transistor configuring the transmission gate might no longer enable transmission of the data D to the next stage in the case where the power supply voltage is low.

Therefore, for the sixth embodiment, an enabled clocked inverter is used as a component of the master latch 101 to, thereby, eliminate the above described failure.

The enabled clocked inverter includes a first type illustrated in FIG. 21A and a second type illustrate in FIG. 21B.

The first type consists of a CMOS inverter consisting of the N-type and P-type MOS transistors P102 and N102, two switch elements consisting of the N-type and P-type MOS transistors P101 and N101 and two switch elements consisting of the N-type and P-type MOS transistors P103 and N103.

The second type consists of a CMOS inverter consisting of the N-type and P-type MOS transistors P101 and N101, two switch elements consisting of the N-type and P-type MOS transistors P102 and N102 and two switch elements consisting of the N-type and P-type MOS transistors P103 and N103.

For the first type, when the MOS transistor P101 having been put off with the clock is put on and is supplied with power supply, that MOS transistor P101 having been put on cannot drive a load to change the output unless ON resistance or parasite capacitance of the MOS transistor P102 is charged first.

On the other hand, for the second type, when the MOS transistor P102 having been put off with the clock is put on, a power supply voltage VDD is already applied to the MOS transistor P101 and, therefore, electric potential of the MOS transistor P101 is defined. Therefore, the MOS transistor P102 only has to drive a load and the delay time of the second type is shorter.

Therefore, a circuit of the second type in FIG. 21B is adopted for the enabled clocked inverters 112 and 113 configuring the master latch 101 in FIG. 20.

That is, as illustrated in FIG. 21B, the enabled clocked inverters 112 and 113 in FIG. 20 consist of a CMOS inverter configured by the P-type and N-type MOS transistors P101 and N101 and a P-type and N-type MOS transistors P102 and N102 being switch elements controlling ON-OFF on an output logic of that CMOS inverter and a P-type and N-type MOS transistors P103 and N103 bringing the CMOS inverter, the power supply and the ground into connection. The gate electrodes of the MOS transistors P101 and N101 are brought into common connection and the common connection part is supplied with an input signal IN. The gate electrodes of the MOS transistors P102 and N102 are respectively supplied with the clocks C and /C. The gate electrodes of the MOS transistors P103 and N103 are respectively supplied with the enable signal EN and /EN.

The P-type and N-type MOS transistors P101 and N101 configuring the above described CMOS inverter and the P-type and N-type MOS transistors P103 and N103 configuring the switch element are formed by using two pairs among the main MOS transistors 72, 73, 76 and 77 of the basic cell 7 in FIG. 2. The P-type and N-type MOS transistors P102 and N102 configuring the switch element are formed by using the auxiliary MOS transistors 74 and 78 of that same basic cell 7.

As illustrated in FIG. 22, the inverter 111 in FIG. 20 consists of a CMOS inverter configured by the P-type MOS transistor P104 and the N-type MOS transistor N104. The P-type and N-type MOS transistors P104 and N104 thereof are formed by using the auxiliary MOS transistors 74 and 78 of the basic cell 7 in FIG. 2.

The reason why the inverter 111 is formed thus by using the auxiliary MOS transistors 74 and 78 of the basic cell 7 is as follows. That is, the gate capacity of the inverter 111 undergoes buffering as a scan data line at the occasion of a layout on a chip level and, therefore, its transistor size is preferably smaller.

As illustrated in FIG. 23, the inverter 115 configuring the latch circuit 114 in FIG. 20 consists of a CMOS inverter configured by the P-type MOS transistor P105 and the N-type MOS transistors N105. The P-type and N-type MOS transistors P105 and N105 configuring that CMOS inverter is formed by using a pair among the main MOS transistors 72, 73, 76 and 77 of the basic cell 7 in FIG. 2. The reason why the main MOS transistors are used is that the inverter 115 is on a data propagation path from the input terminals 104a and 104b to reach the output terminal 106 as illustrated in FIG. 20.

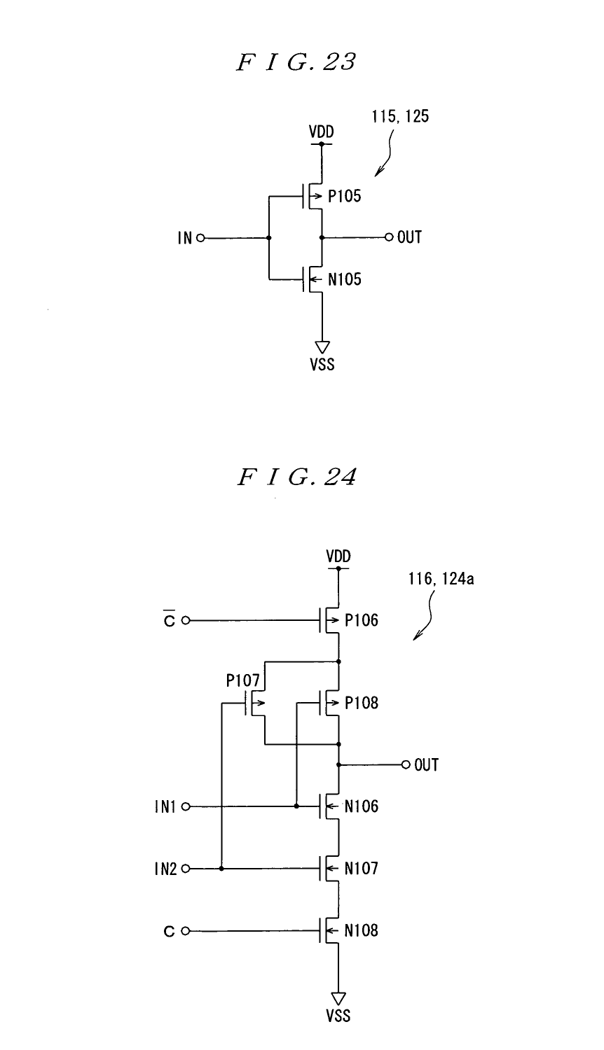

As illustrated in FIG. 24, the clocked NAND gate 16 configuring the latch circuit 114 in FIG. 20 comprises NAND gate consisting of the P-type MOS transistors P107 and P108 brought into connection in parallel and the N-type MOS transistors N106 and N107 brought into cascade connection and, moreover, comprises the P-type MOS transistor P106 and the N-type MOS transistor N108 being switch elements controlling ON-OFF between that NAND gate and the power supply voltage VDD and the ground voltage VSS.

An input signal IN1 is input to the gate electrodes of the MOS transistors P108 and N106 configuring the NAND gate and an input signal IN2 is input to the respective gate electrodes of the MOS transistors P107 and N107. The gate electrodes of the MOS transistors P106 and N108 are respectively supplied with the clocks C and /C.

The reason why a circuit provided with the MOS transistors P106 and N108 on the side of the power supply is adopted for the clocked NAND gate 116 as illustrated in FIG. 24 is as follows. That is, the clocked NAND gate 116 configures the wired OR logic with the enabled clocked inverters 112 and 113. Therefore, for the clocked NAND gate 116, a circuit illustrated in FIG. 24 which expands delay on the contrary to the enabled clocked inverters 112 and 113 is adopted.

For the clocked NAND gate 116, the P-type MOS transistors P107 and P108 and the N-type MOS transistors N106 and N107 configuring the NAND gate are formed by using the main MOS transistors 72, 73, 76 and 77 of the basic cell 7 in FIG. 2. The P-type and N-type MOS transistors P106 and N108 configuring the switch element are formed by using the auxiliary MOS transistors 74 and 78 of that same basic cell 7. Accordingly, the clocked NAND gate 116 in FIG. 24 can be configured only by the basic cell 7 in FIG. 2.

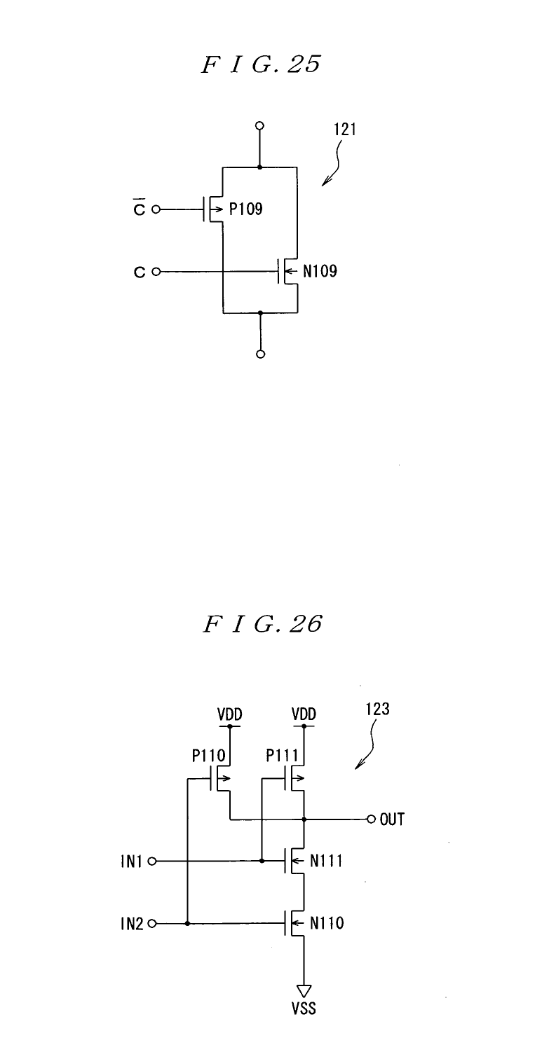

As illustrated in FIG. 25, the transmission gate 121 in FIG. 20 consists of the P-type MOS transistor P109 and the N-type MOS transistor N109, which are brought into connection in parallel. The gate electrodes of the MOS transistors P109 and N109 are respectively supplied with the clocks C and /C. The P-type and N-type MOS transistors P109 and N109 configuring the transmission gate 121 is formed by using a pair among the main MOS transistors 72, 73, 76 and 77 of the basic cell 7 in FIG. 2. The reason why the main MOS transistors are used thus is that the transmission gate 121 is on a data propagation path from the input terminals 104a and 104b to reach the output terminal 106 as illustrated in FIG. 20.

As illustrated in FIG. 26, the NAND gate 123 configuring the latch circuit 122 in FIG. 20 consists of P-type MOS transistors P110 and P111 brought into coupling in parallel and the N-type MOS transistors N110 and N111 brought into cascade coupling. A reset signal R is input as the input signal IN1 to the respective gate electrodes of the MOS transistors P111 and N111. Data are input as the input signal IN2 to the respective gate electrodes of the MOS transistors P110 and N110.

In addition, the NAND gate 123 is on a data propagation path from the input terminals 104a and 104b to reach the output terminal 106 as illustrated in FIG. 26 and data are input thereto. Therefore, the MOS transistors P110 and N110 to which data are input are formed by using a pair among the main MOS transistors 72, 73, 76 and 77 of the basic cell 7 in FIG. 2. In addition, the reset signal R is input to the NAND gate 123 and the reset signal line thereof undergoes buffering. Therefore, a smaller MOS transistor is preferable. Therefore, the MOS transistors P111 and N111 to which the reset signal R is input are formed by using the auxiliary MOS transistors 74 and 78 of that same basic cell 7.

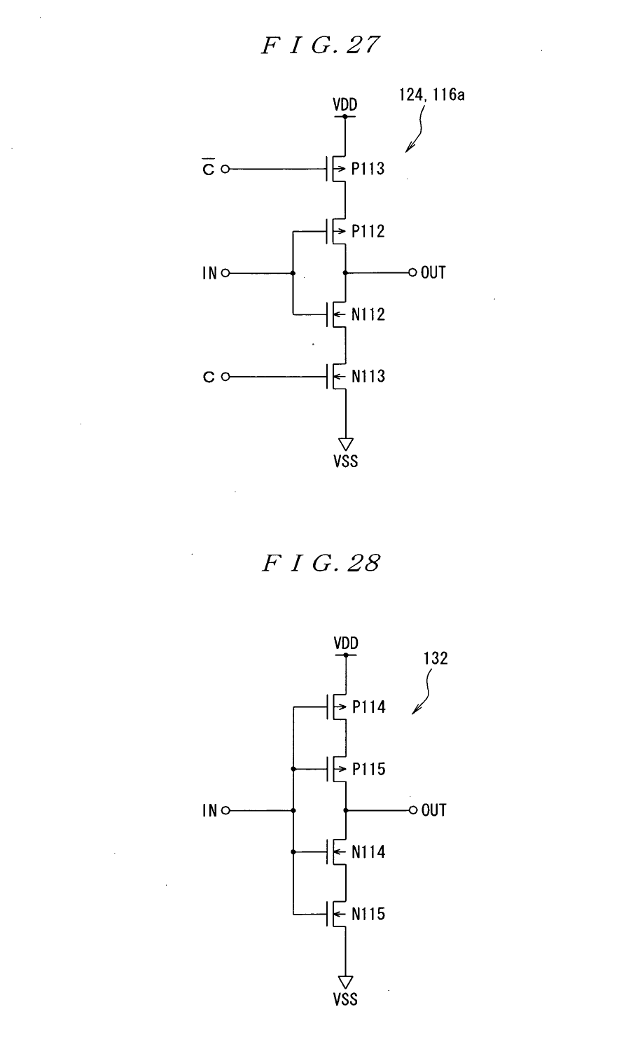

As illustrated in FIG. 27, the clocked inverter 124 configuring the latch circuit 122 in FIG. 20 consists of a CMOS inverter configured by the P-type MOS transistor P112 and the N-type MOS transistor N112 and the P-type MOS transistor P113 and the NMOS transistor N113 being switch elements controlling ON-OFF between that CMOS inverter and the power supply voltage VDD and the ground voltage VSS. The gate electrodes of the MOS transistors P112 and N112 are brought into common connection and the common connection part is supplied with an input signal IN. The gate electrodes of the MOS transistors P113 and N113 are respectively supplied with the clocks C and /C.

The reason why a circuit as in FIG. 27 is adopted for the clocked inverter 124 is that the clocked inverter 124 configures the wired OR logic with the transmission gate 121. Therefore, for the clocked inverter 124, a circuit illustrated in FIG. 27 which expands delay on the contrary to the transmission gate 121 is adopted.

The P-type and N-type MOS transistors P112 and N112 configuring the above described CMOS inverter are formed by using a pair among the main MOS transistors 72, 73, 76 and 77 of the basic cell 7 in FIG. 2. The P-type and N-type MOS transistors P113 and N113 configuring the switch element are formed by using the auxiliary MOS transistors 74 and 78 of that same basic cell 7.

The inverter 125 in FIG. 20 is configured likewise the inverter 115 illustrated in FIG. 20 and FIG. 23. The reason thereof is that the inverter 125 is on a data propagation path from the input terminals 104a and 104b to reach the output terminal 106 likewise the inverter 115 (see FIG. 20).

As illustrated in FIG. 22, the inverter 131 in FIG. 20 consists of a CMOS inverter configured by the P-type MOS transistor P104 and the N-type MOS transistor N104. Those P-type and N-type MOS transistors P104 and N104 are formed by using the auxiliary MOS transistors 74 and 78 of the basic cell 7 in FIG. 2.

The reason why the inverter 131 is formed thus by using the auxiliary MOS transistors 74 and 78 of the basic cell 7 is as follows. That is, the gate capacity of the inverter 131 undergoes buffering as a clock line at the occasion of a layout on a chip level and, therefore, its transistor size is preferably smaller.

As illustrated in FIG. 28, the inverter 132 in FIG. 20 is configured by bringing the P-type MOS transistors P114 and P115 and the N-type MOS transistors N114 and N115 into cascade connection to configure a CMOS inverter. The MOS transistors P114, P115, N114 and N115 configuring that CMOS inverter are formed by using the main MOS transistors 72, 73, 76 and 77 of the basic cell 7 in FIG. 2.

The reason why the inverter 132 is formed thus is as follows. That is, the inverter 132 is a necessary logic circuit for configuring a circuit. However, although a small-sized MOS transistor is sufficient in consideration of Fan Out and the pass-through current amount, the auxiliary MOS transistors 74 and 78 of the basic cell 7 forming the inverter 131 cannot be used.

Therefore, for the inverter 132, main MOS transistors 72,73,76 and 77 of the basic cell 7 is brought into cascade connection to configure a CMOS inverter so that a circuit equivalent to the CMOS inverter with the auxiliary MOS transistors 74 and 78 is obtained. Thereby, the inverters 131 and 132 can be formed with the same basic cell 7 and can utilize the basic cell 7 effectively.

As described above, in the sixth embodiment, a master-slave type flip-flop is configured with a gate array. As illustrated in FIG. 2, the basic cell of that gate array consisting of four main MOS transistors and two auxiliary MOS transistors is used. Moreover, the logic circuits of respective parts configuring the flip-flop are configured by combining those six MOS transistors so as to become optimum according to applications and functions thereof.

Therefore, according to the sixth embodiment, reduction in power consumption and reduction in EMI can be planned. In addition, according to the sixth embodiment, the basic cell can be utilized effectively at the occasion of forming respective types of logic circuits and wiring resource can be secured to plan simplification of wiring.

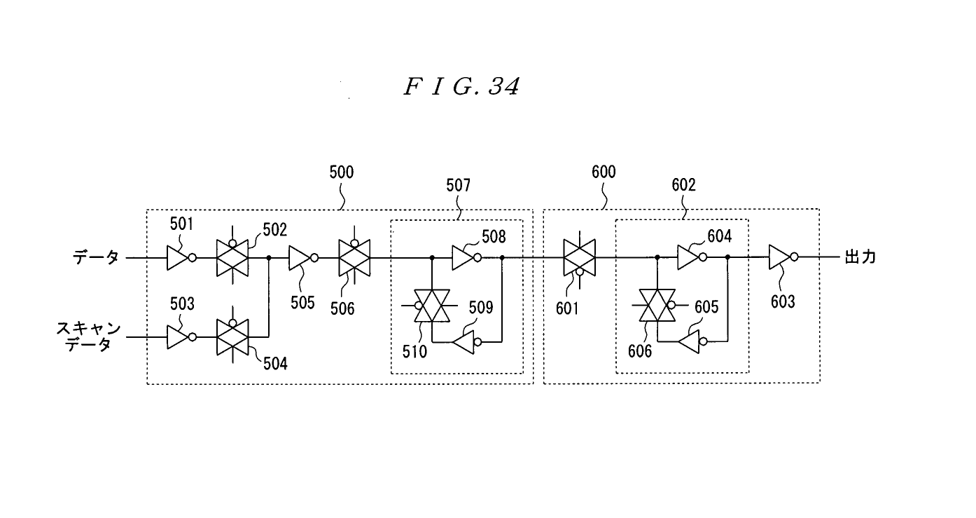

Here, in order to confirm specific effects of reduction in EMI in the sixth embodiment, the sixth embodiment and the conventional flip-flop (conventional circuit) illustrated in FIG. 34 have undergone measurement on the frequency component of noise included in a power supply current respectively. Then, a measurement result thereof as in the case of the first embodiment is obtained (see FIGS. 12A and 12B).

### Seventh Embodiment

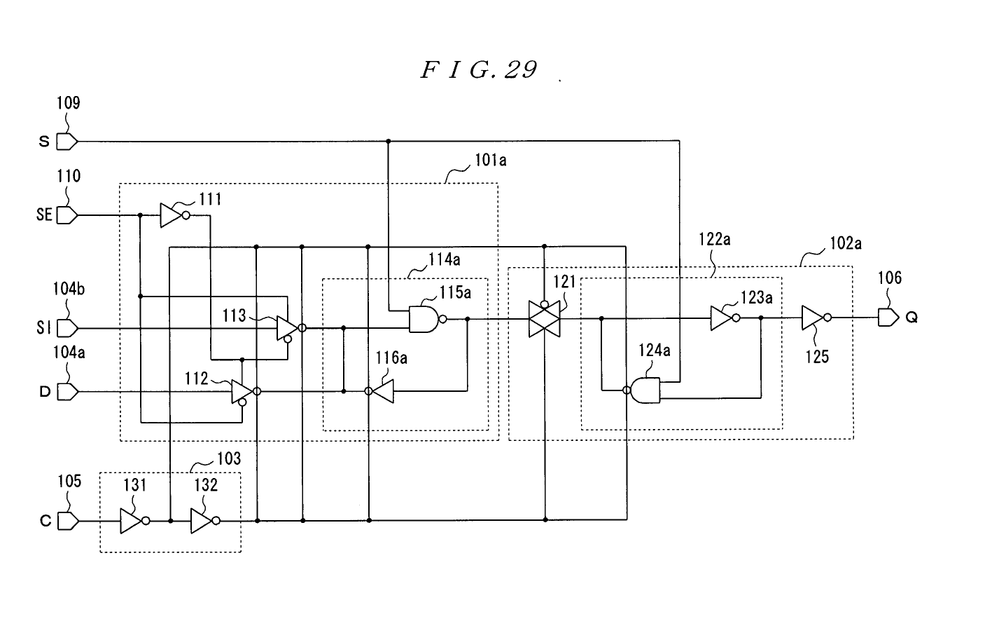

As illustrated in FIG. 29, a seventh embodiment related to a master-slave type flip-flop circuit of the invention comprises a master latch 101a, a slave latch 102a and a clock supply circuit 103 supplying a clock thereto; is operated with a rise of the clock; and has a set function.

In addition, the seventh embodiment is applicable to scan design being one of test simplification designing of an integrated circuit and can take in and retain the scan data at the time of a test operation and can take in and retain data at the time of a normal operation.

That is, the seventh embodiment is basically configured likewise the sixth embodiment illustrated in FIG. 20 and the master latch 101 and the slave latch 102 in FIG. 20 are replaced by the master latch 101a and the slave latch 102a.

Here, the seventh embodiment is basically configured likewise the sixth embodiment. Therefore, like reference numerals and characters designate the same components so that description thereon is omitted as much as possible.

The master latch 101a inputs data D supplied to the input terminal 104a at the time of a normal operation; inputs scan data SI supplied to the input terminal 104b at the time of a test operation; and takes in and retains the input data according to a logic of the clock C being input to the clock terminal 105. In addition, the set signal S being input to the set terminal 109 can set a state inside the master latch 101a irrespective of the logic of the clock C being input to the clock terminal 105. Therefore, the master latch 101a consists of an inverter 111, enabled clocked inverters 112 and 113 and a latch circuit 114a.

The latch circuit 114a configures a closed circuit with a NAND gate 115a with two inputs and a clocked inverter 116a so as to be capable of taking in and retaining data. In addition, in order to set a state inside the master latch 101a, a set signal S is input to an input terminal of the NAND gate 115a.

A slave latch 102a takes in and retains data from the master latch 101a according to a logic of the clock C being input to the clock terminal 105 and outputs the data to an output terminal 106. The slave latch 102a sets the state inside the slave latch with a set signal S irrespective of the logic of the clock C being input to the clock terminal 105. Therefore, the slave latch 102a consists of a transmission gate 121, a latch circuit 122a and an inverter 125.

The latch circuit 122a configures a closed circuit with an inverter 123a and clocked NAND gate 124a with two inputs so as to be capable of retaining data. In addition, in order to set the data, the set signal S is input to the input terminal of the clocked NAND gate 124a. The data retained by the latch circuit 122a are output from an output terminal 106 through the inverter 125.

The inverted clock /C inverted by the inverter 131 and the clock C being output from the inverter 132 are supplied to the enabled clocked inverters 112 and 113, the clocked inverter 116a, the transmission gate 121 and the clocked NAND gate 124a respectively.

For a seventh embodiment, respective components configuring a master latch 101a, a slave latch 102a and a clock supply circuit 103 are realized with MOS transistors of a basic cell 7 illustrated in FIG. 2. Therefore, the configuration example thereof will be described.

Comparing the configuration of the seventh embodiment with the configuration of the sixth embodiment in FIG. 20, configurations of the latch circuit 114a and the latch circuit 122a are different and configurations of the other portions are the same as the configuration of the sixth embodiment and, therefore, description thereon will be omitted.

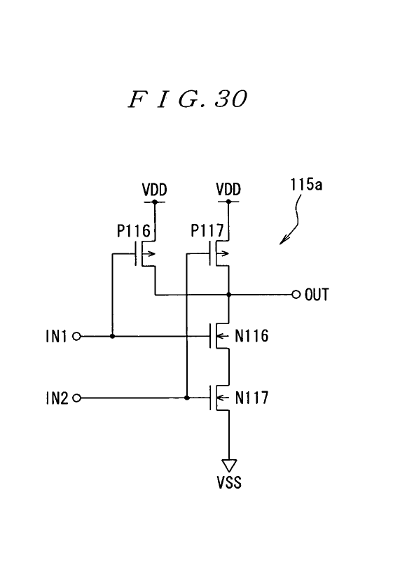

As illustrated in FIG. 30, the NAND gate 115a configuring the latch circuit 114a consists of the P-type MOS transistors P116 and P117 brought into connection in parallel and the N-type MOS transistors N116 and N117 brought into cascade connection. Data are input to the respective gate electrodes of the MOS transistors P116 and N116 as an input signal IN1. A set signal S is input as the input signal IN2 to the respective gate electrodes of the MOS transistors P117 and N117.

In addition, the NAND gate 115a is on a data propagation path from the input terminals 104a and 104b to reach the output terminal 106 as illustrated in FIG. 29 and data are input thereto. Therefore, the MOS transistors P116 and N116 to which data are input are formed by using a pair among the main MOS transistors 72, 73, 76 and 77 of the basic cell 7 in FIG. 2. In addition, the set signal S is input to the NAND gate 115a and the set signal line thereof undergoes buffering. Therefore, a smaller MOS transistor is preferable. Therefore, the MOS transistors P117 and N117 to which the set signal S is input are formed by using the auxiliary MOS transistors 74 and 78 of that same basic cell 7.

The clocked inverter 116a configuring the latch circuit 114a is configured likewise the clocked inverter 124 illustrated in FIG. 20 and FIG. 27. The reason why a circuit as in FIG. 27 is adopted for the clocked inverter 116a is that the clocked inverter 116a configures the wired OR logic with the enabled clocked inverters 112 and 113. Therefore, for the clocked inverter 116a, a circuit illustrated in FIG. 27 which expands delay on the contrary to the enabled clocked inverters 112 and 113 is adopted.

The P-type and N-type MOS transistors P112 and N112 configuring the above described CMOS inverter are formed by using a pair among the main MOS transistors 72, 73, 76 and 77 of the basic cell 7 in FIG. 2. The P-type and N-type MOS transistors configuring the switch element are formed by using the auxiliary MOS transistors 74 and 78 of that same basic cell 7.

The inverter 123a configuring the latch circuit 122a is configured likewise the inverter 115 illustrated in FIG. 20 and FIG. 23. The reason thereof is that the inverter 123a is on a data propagation path from the input terminals 104a and 104b to reach the output terminal 106 likewise the inverter 115 (see FIG. 29).

The clocked NAND gate 124a configuring the latch circuit 122a is configured likewise the clocked NAND gate 116 illustrated in FIG. 20 and FIG. 24.

The reason why a circuit provided with the MOS transistors P106 and N108 on the side of the power supply is adopted for the clocked NAND gate 124a as illustrated in FIG. 24 is as follows. That is, the clocked NAND gate 124a configures the wired OR logic with the transmission gate 121. Therefore, for the clocked NAND gate 124a, a circuit illustrated in FIG. 24 which expands delay on the contrary to the transmission gate 121 is adopted.

According to the seventh embodiment described above, a set signal can set data and, moreover, the effect likewise the sixth embodiment can be realized.

### Eighth Embodiment

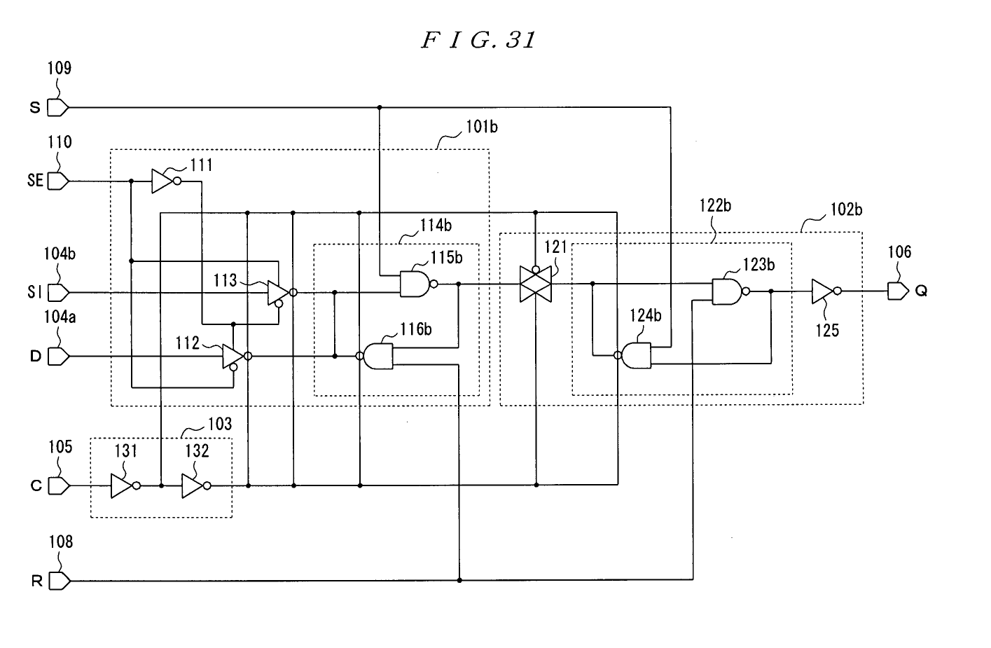

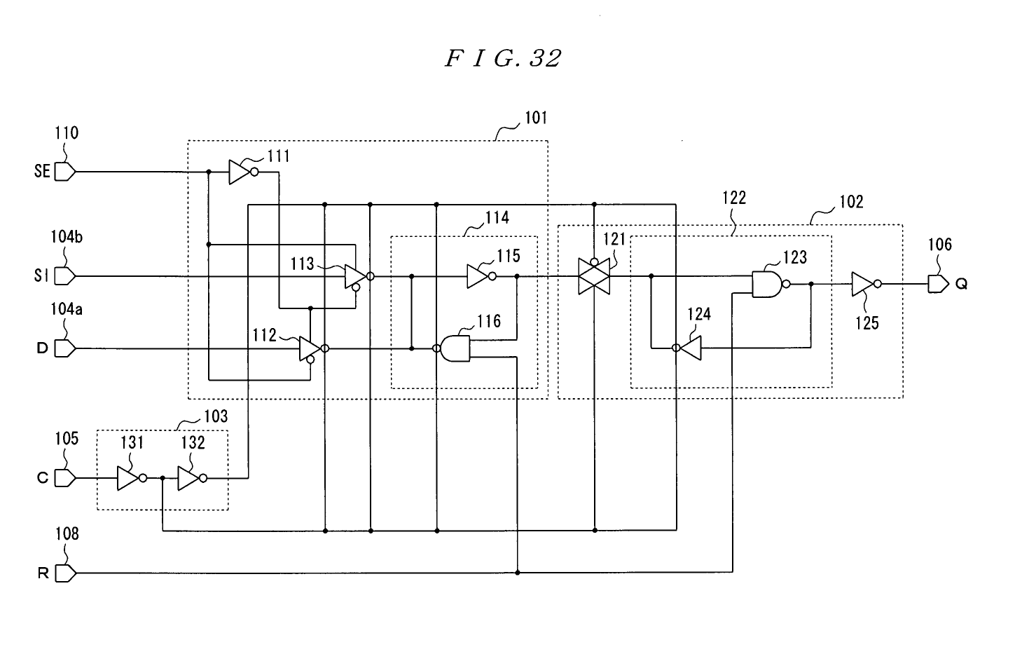

As illustrated in FIG. 31, an eighth embodiment related to a master-slave type flip-flop circuit of the invention comprises a master latch 101b, a slave latch 102b and a clock supply circuit 103 supplying a clock thereto; is operated with a rise of the clock; and has set and reset functions.

In addition, the eighth embodiment is applicable to scan design being one of test simplification designing of an integrated circuit and can take in and retain the scan data at the time of a test operation and can take in and retain data at the time of a normal operation.

That is, the eighth embodiment is basically configured likewise the sixth embodiment illustrated in FIG. 20 and the master latch 101 and the slave latch 102 in FIG. 20 are replaced by the master latch 101b and the slave latch 102b.

Here, the eighth embodiment is basically configured likewise the sixth embodiment. Therefore, like reference numerals and characters designate the same components so that description thereon is omitted as much as possible.

The master latch 101b inputs data D supplied to the input terminal 104a at the time of a normal operation; inputs scan data SI supplied to the input terminal 104b at the time of a test operation; and takes in and retains the input data according to a logic of the clock C being input to the clock terminal 105. In addition, the set signal S being input to the set terminal 109 can set a state inside the master latch 101b irrespective of the logic of the clock C being input to the clock terminal 105 and the reset signal R being input to the reset terminal 108 can reset a state inside the master latch 101b according to a logic of the clock C being input to the clock terminal 105.

Therefore, the master latch 101b consists of an inverter 111, enabled clocked inverters 112 and 113 and a latch circuit 114b. The latch circuit 114b configures a closed circuit with a NAND gate 115b with two inputs and a clocked NAND gate 116b with two inputs so as to be capable of retaining data. In addition, in order to set the data, the set signal S is input to the input terminal of the NAND gate 115b. Moreover, in order to reset the data, a reset signal R is input to an input terminal of the clocked NAND gate 116b.

A slave latch 102b takes in and retains data from the master latch 101b according to a logic of the clock C being input to the clock terminal 105 and outputs the data to an output terminal 106. The slave latch 102b is designed to be capable of setting the state inside the slave latch with a set signal S irrespective of the logic of the clock C being input to the clock terminal 105 and capable of resetting the state inside the slave latch with the reset signal R irrespective of a logic of the clock C being input to the clock terminal 105.

Therefore, the slave latch 102b consists of a transmission gate 121, a latch circuit 122b and an inverter 125. The latch circuit 122b configures a closed circuit with a NAND gate 123b with two inputs and a clocked NAND gate 124b with two inputs so as to be capable of retaining data. In addition, in order to set the data, the set signal S is input to the input terminal of the clocked NAND gate 124b. Moreover, in order to reset the data, the reset signal R is input to the input terminal of the NAND gate 123b.

The inverted clock /C inverted by the inverter 131 and the clock C being output from the inverter 132 are supplied to the enabled clocked inverters 112 and 113, clocked NAND gates 116b and 124b and the transmission gate 121 respectively.

Next, for an eighth embodiment, respective components configuring a master latch 101b, a slave latch 102b and a clock supply circuit 103 are realized with MOS transistors of a basic cell 7 illustrated in FIG. 2. Therefore, the configuration example thereof will be described.

Comparing the configuration of the eighth embodiment with the configuration of the sixth embodiment in FIG. 20, configurations of the latch circuit 114b and the latch circuit 122b are different and configurations of the other portions are the same as the configuration of the sixth embodiment and, therefore, description thereon will be omitted.

The NAND gate 115b configuring the latch circuit 114b is configured likewise the NAND gate 115a in FIG. 29 and FIG. 30. The clocked NAND gate 116b configuring the latch circuit 114b is configured likewise the clocked NAND gate 116 in FIG. 20 and FIG. 24.

The NAND gate 123b configuring the latch circuit 122b is configured likewise the NAND gate 123 in FIG. 20 and FIG. 26. The clocked NAND gate 124b configuring the latch circuit 122b is configured likewise the clocked NAND gate 116 in FIG. 29 and FIG. 24.

According to the eighth embodiment described above, a set signal can set data and a reset signal can reset data and, moreover, the effect likewise the sixth embodiment can be realized.

### Ninth Embodiment

As illustrated in FIG. 32, a ninth embodiment related to a master-slave type flip-flop circuit of the invention comprises a master latch 101, a slave latch 102 and a clock supply circuit 103 supplying a clock thereto and is operated with a fall of the clock.

That is, the ninth embodiment is basically configured likewise the sixth embodiment illustrated in FIG. 20 and a destination supplied with the clock being output from the clock supply circuit 103 is changed as in FIG. 32 from FIG. 20 so that the master latch 101 and the slave latch 102 are operated with a fall of the clock.

Here, the respective seventh and eighth embodiments described above are operated with a rise of the clock but can be operated with a fall of the clock. In that case, the destination supplied with the clock being output from the clock supply circuit 103 can be changed likewise the ninth embodiment.

1. A master-slave type flip-flop circuit consisting of a master latch and a slave latch,
wherein the master latch comprises:
a first clocked inverter to which data are input and
a first latch circuit configuring a closed circuit with a first inverter and a second clocked inverter so that an output of the first clocked inverter is input to the first inverter and;
the slave latch comprises:
a transmission gate to which an output from the first latch circuit is input and
a second latch circuit configuring a closed circuit with a second inverter and a third clocked inverter so that an output of the transmission gate is input to the second inverter,
respective components configuring the master latch and the slave latch are configured with Sea Of Gate (hereinafter to be referred to as SOG) configuring a gate array,
a basic cell of the SOG consists of triplely arrayed N-type transistors and corresponding triplely arrayed P-type transistors,
the triplely arrayed N-type transistors consist of double-arrayed normally sized main transistors and one auxiliary transistor sized smaller than in a normal size and
the triplely arrayed P-type transistors consist of double-arrayed normally sized main transistors and one auxiliary transistor sized smaller than in a normal size.

2. The master-slave type flip-flop circuit according to claim 1, further comprising a clock supply circuit supplying the master latch and the slave latch respectively with a clock,
wherein the clock supply circuit consists of
a third inverter inverting a logic of a clock signal being input;
a fourth inverter inverting an output logic of the third inverter; and
the third and fourth inverters are configured with the basic cell.

3. The master-slave type flip-flop circuit according to claim 1,
wherein the first clocked inverter consists of a fifth inverter and two first switches carrying out on-off control of a logic of an output of the fifth inverter;
the fifth inverter is configured by P-type and N-type main transistors configuring the basic cell and the two first switches are configured by P-type and N-type auxiliary transistors configuring the same basic cell;
the second and the third clocked inverters respectively consist of a sixth inverter and two second switches carrying out on-off control of connection between the sixth inverter and a power supply as well as the ground;
the sixth inverter is configured by P-type and N-type main transistors configuring the basic cell and
the two second switches are configured by P-type and N-type auxiliary transistors configuring the same basic cell and
the first inverter, the transmission gate and the second inverter are respectively configured by P-type and N-type main transistors configuring the basic cell.

4. The master-slave type flip-flop circuit according to claim 2,
wherein the third inverter is configured by P-type and N-type auxiliary transistors configuring the basic cell and
the fourth inverter is configured by bringing two P-type main transistors and two N-type main transistors configuring the same basic cell into cascade connection.

5. A master-slave type flip-flop circuit consisting of a master latch and a slave latch,
wherein the master latch comprises:
a first clocked inverter to which data are input and
a first latch circuit configuring a closed circuit with a first inverter and a first clocked NAND gate so that an output of the first clocked inverter is input to the first inverter and a reset signal is input to the first clocked NAND gate;
the slave latch comprises:
transmission gate to which an output from the first latch circuit is input and
a second latch circuit configuring a closed circuit with a first NAND gate and a second clocked inverter so that an output of the transmission gate and the reset signal are input to the second clocked NAND gate,
respective components configuring the master latch and the slave latch are configured with SOG configuring a gate array,
a basic cell of the SOG consists of triplely arrayed N-type transistors and corresponding triplely arrayed P-type transistors,
the triplely arrayed N-type transistors consist of double-arrayed normally sized main transistors and one auxiliary transistor sized smaller than in a normal size and
the triplely arrayed P-type transistors consist of double-arrayed normally sized main transistors and one auxiliary transistor sized smaller than in a normal size.

6. The master-slave type flip-flop circuit according to claim 5,
wherein the first clocked inverter consists of a third inverter and two first switches carrying out on-off control of a logic of an output of the third inverter;
the third inverter is configured by P-type and N-type main transistors configuring the basic cell and the two first switches are configured by P-type and N-type auxiliary transistors configuring the same basic cell;
the second clocked inverter consists of a fourth inverter and two second switches carrying out on-off control of connection between the fourth inverter and a power supply as well as the ground;
the fourth inverter is configured by P-type and N-type main transistors configuring the basic cell and
the two second switches are configured by P-type and N-type auxiliary transistors configuring the same basic cell and
the first clocked NAND gate consists of a NAND gate and a third switch carrying out on-off control of connection between the NAND gate and a power supply as well as the ground;
the NAND gate is configured by four P-type and N-type main transistors configuring the basic cell and the two third switches are configured by the two remaining P-type and N-type auxiliary transistors of the same basic cell;
the first inverter and the transmission gate are respectively configured by P-type and N-type main transistors configuring the basic cell; and
the first NAND gate is configured by P-type and N-type main transistors and auxiliary transistors configuring the basic cell.

7. A master-slave type flip-flop circuit consisting of a master latch and a slave latch,
wherein the master latch comprises:
a first clocked inverter to which data are input and
a first latch circuit configuring a closed circuit with a first NAND gate and a second clocked inverter so that a logic of an output of the first clocked inverter and the set signal are input to the first NAND gate and
wherein the slave latch comprises:
transmission gate to which an output from the first latch circuit is input and
a second latch circuit configuring a closed circuit with a first inverter and a first clocked NAND gate so that an output of the transmission gate is input to the first inverter and the reset signal is input to the first clocked NAND gate,
respective components configuring the master latch and the slave latch are configured with SOG configuring a gate array,
a basic cell of the SOG consists of triplely arrayed N-type transistors and corresponding triplely arrayed P-type transistors,
the triplely arrayed N-type transistors consist of double-arrayed normally sized main transistors and one auxiliary transistor sized smaller than in a normal size and
the triplely arrayed P-type transistors consist of double-arrayed normally sized main transistors and one auxiliary transistor sized smaller than in a normal size.

8. The master-slave type flip-flop circuit according to claim 7,
wherein the first clocked inverter consists of a third inverter and two first switches carrying out on-off control of a logic of an output of the third inverter;
the third inverter is configured by P-type and N-type main transistors configuring the basic cell and the two first switches are configured by P-type and N-type auxiliary transistors configuring the same basic cell;
the second clocked inverter consists of a fourth inverter and two second switches carrying out on-off control of connection between the fourth inverter and a power supply as well as the ground;
the fourth inverter is configured by P-type and N-type main transistors configuring the basic cell and the two second switches are configured by P-type and N-type auxiliary transistors configuring the same basic cell and
the first clocked NAND gate consists of a NAND gate and a third switch carrying out on-off control of connection between the NAND gate and a power supply as well as the ground;
the NAND gate is configured by four P-type and N-type main transistors configuring the basic cell and the two third switches are configured by the two remaining P-type and N-type auxiliary transistors of the same basic cell; and
the first NAND gate, the transmission gate and the first inverter are respectively configured by P-type and N-type main transistors configuring the basic cell.

9. A master-slave type flip-flop circuit consisting of a master latch and a slave latch,
wherein the master latch comprises:
a first clocked inverter to which data are input and
a first latch circuit configuring a closed circuit with a first NAND gate and a first clocked NAND gate so that a logic of an output of the first clocked inverter and the reset signal are respectively input to the first NAND gate and the set signal is input to the first clocked NAND gate and
wherein the slave latch comprises:
transmission gate to which an output from the first latch circuit is input and
a second latch circuit configuring a closed circuit with a second NAND gate and a second clocked NAND gate so that the reset signal is input to the second NAND gate and the set signal is input to the second clocked NAND gate and
respective components configuring the master latch and the slave latch are configured with SOG configuring a gate array,
a basic cell of the SOG consists of triplely arrayed N-type transistors and corresponding triplely arrayed P-type transistors,
the triplely arrayed N-type transistors consist of double-arrayed normally sized main transistors and one auxiliary transistor sized smaller than in a normal size and
the triplely arrayed P-type transistors consist of double-arrayed normally sized main transistors and one auxiliary transistor sized smaller than in a normal size.

10. The master-slave type flip-flop circuit according to claim 9,
wherein the first clocked inverter consists of a third inverter and two first switches carrying out on-off control of a logic of an output of the third inverter;
the third inverter is configured by two P-type and N-type main transistors configuring the basic cell and the two first switches are configured by P-type and N-type auxiliary transistors configuring the same basic cell;
the first clocked NAND gate and the second clocked NAND gate respectively consist of NAND gates and second switches carrying out on-off control of connection between the NAND gate and a power supply as well as the ground;
the NAND gate is configured by four P-type and N-type main transistors configuring a basic cell and the second switch is configured by the two remaining P-type and N-type auxiliary transistors of the same basic cell; and
the first NAND gate, the transmission gate and the second NAND gate are respectively configured by P-type and N-type main transistors configuring the basic cell.

11. A master-slave type flip-flop circuit consisting of a master latch and a slave latch,
wherein the master latch comprises:
a first enabled clocked inverter to which data are input at the time of a normal operation;
a second enabled clocked inverter to which scan data are input at the time of a test operation;
a first inverter selectively controlling an operation of the first enabled clocked inverter and an operation of the second enabled clocked inverter based on a scan enable signal;
a first latch circuit configuring a closed circuit with a second inverter and a first clocked NAND gate so that a logic of an output of the first or second enabled clocked inverter is input to the second inverter and a reset signal is input to the first clocked NAND gate;
the slave latch comprises:
transmission gate to which an output from the first latch circuit is input and
a second latch circuit configuring a closed circuit with a first NAND gate and a first clocked inverter so that an output of the transmission gate and the reset signal are input to the first NAND gate,
respective components configuring the master latch and the slave latch are configured with SOG configuring a gate array,
a basic cell of the SOG consists of triplely arrayed N-type transistors and corresponding triplely arrayed P-type transistors,
the triplely arrayed N-type transistors consist of double-arrayed normally sized main transistors and one auxiliary transistor sized smaller than in a normal size and
the triplely arrayed P-type transistors consist of double-arrayed normally sized main transistors and one auxiliary transistor sized smaller than in a normal size.

12. The master-slave type flip-flop circuit according to claim 11, further comprising a clock supply circuit supplying the master latch and the slave latch respectively with a clock,
wherein the clock supply circuit consists of
a third inverter inverting a logic of a clock signal being input;
a fourth inverter inverting a logic of an output of the third inverter; and
the third and fourth inverters are configured with the basic cell.

13. The flip-flop circuit according to claim 11,
wherein the first and second enabled clocked inverters respectively consist of first CMOS inverters, two first switches carrying out on-off control of a logic of an output of the first CMOS inverter and two second switches carrying out on-off control of connection between the first CMOS inverter and a power supply as well as the ground based on a scan enable signal;
the first CMOS inverter is configured by P-type and N-type main transistors configuring the basic cell; the two first switches are configured by P-type and N-type auxiliary transistors configuring the same basic cell; and the two second switches are configured by P-type and N-type main transistors configuring the same basic cell;
the first clocked NAND gate consists of a NAND gate and a third switch carrying out on-off control of connection between the NAND gate and a power supply as well as the ground;
the NAND gate is configured by four P-type and N-type main transistors configuring the basic cell and the two third switches are configured by the two remaining P-type and N-type auxiliary transistors of the same basic cell; and
the first clocked inverter consists of a second CMOS inverter and two second switches carrying out on-off control of connection between the second CMOS inverter and a power supply as well as the ground;
the second CMOS inverter is configured by P-type and N-type main transistors configuring a basic cell and the two second switches are configured by P-type and N-type auxiliary transistors configuring the same basic cell;
the first inverter is configured by P-type and N-type auxiliary transistors configuring the same basic cell; and
the second inverter and the transmission gate are respectively configured by P-type and N-type main transistors configuring the basic cell; and
the first NAND gate is configured by P-type and N-type main transistors and auxiliary transistors configuring the basic cell.

14. The master-slave type flip-flop circuit according to claim 12,
wherein the third inverter consists of a CMOS inverter and the CMOS inverter is configured by P-type and N-type auxiliary transistors configuring the basic cell;
the fourth inverter consists of a CMOS inverter and the CMOS inverter is configured by bringing two P-type main transistors and two N-type main transistors configuring the same basic cell into cascade connection.

15. A master-slave type flip-flop circuit consisting of a master latch and a slave latch,
wherein the master latch comprises:
a first enabled clocked inverter to which data are input at the time of a normal operation;
a second enabled clocked inverter to which scan data are input at the time of a test operation;
a first inverter selectively controlling an operation of the first enabled clocked inverter and an operation of the second enabled clocked inverter based on a scan enable signal;
a first latch circuit configuring a closed circuit with a first NAND gate and a first clocked inverter so that a logic of an output of the first or second enabled clocked inverter and a set signal are respectively input to the first NAND gate;
the slave latch comprises:
transmission gate to which an output from the first latch circuit is input and
a second latch circuit configuring a closed circuit with a second inverter and a first clocked NAND gate so that an output of the transmission gate is input to the second inverter and a reset signal is input to the first clocked NAND gate;
respective components configuring the master latch and the slave latch are configured with SOG configuring a gate array,
a basic cell of the SOG consists of triplely arrayed N-type transistors and corresponding triplely arrayed P-type transistors,
the triplely arrayed N-type transistors consist of double-arrayed normally sized main transistors and one auxiliary transistor sized smaller than in a normal size and
the triplely arrayed P-type transistors consist of double-arrayed normally sized main transistors and one auxiliary transistor sized smaller than in a normal size.

16. The master-slave type flip-flop circuit according to claim 15,
wherein the first and second enabled clocked inverters respectively consist of first CMOS inverters, two first switches carrying out on-off control of a logic of an output of the first CMOS inverter and two second switches carrying out on-off control of connection between the first CMOS inverter and a power supply as well as the ground based on a scan enable signal;
the first CMOS inverter is configured by P-type and N-type main transistors configuring the basic cell, the two first switches are configured by P-type and N-type auxiliary transistors configuring the same basic cell and the two second switches are configured by P-type and N-type main transistors configuring the same basic cell;
the first clocked inverter consists of a first CMOS inverter and two third switches carrying out on-off control of an output of the first CMOS inverter;
the first CMOS inverter is configured by P-type and N-type main transistors configuring the basic cell and the two third switches are configured by P-type and N-type auxiliary transistors configuring the same basic cell;
the first clocked NAND gate consists of a NAND gate and a fourth switch carrying out on-off control of connection between the NAND gate and a power supply as well as the ground;
the NAND gate is configured by four P-type and N-type main transistors configuring the basic cell;
the two fourth switches are configured by the two remaining P-type and N-type auxiliary transistors of the same basic cell;
the first inverter is configured by P-type and N-type auxiliary transistors configuring the basic cell; and
the first NAND gate, the transmission gate and the second inverter are respectively configured by P-type and N-type main transistors configuring the basic cell.

17. A master-slave type flip-flop circuit consisting of a master latch and a slave latch,
wherein the master latch comprises:
a first enabled clocked inverter to which data are input at the time of a normal operation;
a second enabled clocked inverter to which scan data are input at the time of a test operation;
a first inverter selectively controlling an operation of the first enabled clocked inverter and an operation of the second enabled clocked inverter based on a scan enable signal;
a first latch circuit configuring a closed circuit with a first NAND gate and a first clocked NAND gate so that a logic of an output of the first or second enabled clocked inverter and the set signal are respectively input to the first NAND gate and the reset signal is input to the first clocked NAND gate and
wherein the slave latch comprises:
transmission gate to which an output from the first latch circuit is input and
a second latch circuit configuring a closed circuit with a second NAND gate and a second clocked NAND gate so that the reset signal is input to the second NAND gate and the set signal is input to the second clocked NAND gate and
respective components configuring the master latch and the slave latch are configured with SOG configuring a gate array;
a basic cell of the SOG consists of triplely arrayed N-type transistors and corresponding triplely arrayed P-type transistors;
the triplely arrayed N-type transistors consist of double-arrayed normally sized main transistors and one auxiliary transistor sized smaller than in a normal size; and
the triplely arrayed P-type transistors consist of double-arrayed normally sized main transistors and one auxiliary transistor sized smaller than in a normal size.

18. The master-slave type flip-flop circuit according to claim 17,
wherein the first and second enabled clocked inverters respectively consist of first CMOS inverters, two first switches carrying out on-off control of a logic of an output of the first CMOS inverter and two second switches carrying out on-off control of connection between the first CMOS inverter and a power supply as well as the ground based on a scan enable signal;
the first CMOS inverter is configured by P-type and N-type main transistors configuring the basic cell; the two first switches are configured by P-type and N-type auxiliary transistors configuring the same basic cell; and the two second switches are configured by P-type and N-type main transistors configuring the same basic cell;
the first clocked NAND gate and the second clocked NAND gate respectively consist of NAND gate and a third switch carrying out on-off control of connection between the NAND gate and a power supply as well as the ground;
the NAND gate is configured by four P-type and N-type main transistors configuring the basic cell and the third switches are configured by the two remaining P-type and N-type auxiliary transistors of the same basic cell; and
the first inverter is configured by P-type and N-type auxiliary transistors configuring the basic cell; and
the first NAND gate, the transmission gate and the second NAND gate are respectively configured by P-type and N-type main transistors configuring the basic cell.
